(19) United States
(12) Patent Application Publication
(10) Pub. No.: US 2025/0259822 A1
(43) Pub. Date: Aug. 14, 2025

(54) BIAS SUPPLY WITH RESONANT SWITCHING

(71) Applicant: Eagle Harbor Technologies Inc., Seattle, WA (US)

(72) Inventors: Timothy Ziemba, Bainbridge Island, WA (US); Kenneth Miller, Seattle, WA (US); James Prager, Seattl, WA (US)

(73) Assignee: Eagle Harbor Technologies Inc., Seattle, WA (US)

(21) Appl. No.: 19/193,940

(22) Filed: Apr. 29, 2025

Related U.S. Application Data
(63) Continuation-in-part of application No. 18/988,870, filed on Dec. 19, 2024.
Application No. 18/988,870 is a continuation of application No. 18/328,411, filed on Jun. 2, 2023, now Pat. No. 12,198,898.
Application No. 18/328,411 is a continuation of application No. 17/231,931, filed on Apr. 15, 2021, now Pat. No. 11,670,484.
Application No. 17/231,931 is a continuation of application No. 16/697,173, filed on Nov. 26, 2019, now Pat. No. 11,004,660.
(63) Continuation-in-part of application No. 17/214,772, filed on Mar. 26, 2021.
Application No. 17/214,772 is a continuation-in-part of application No. 17/133,612, filed on Dec. 23, 2020, now Pat. No. 11,527,383.
Application No. 17/214,772 is a continuation-in-part of application No. PCT/US20/66990, filed on Dec. 23, 2020.
(60) Provisional application No. 62/774,078, filed on Nov. 30, 2018.
(60) Provisional application No. 62/953,259, filed on Dec. 24, 2019.
(60) Provisional application No. 62/953,259, filed on Dec. 24, 2019.

(51) Int. Cl. H01J 37/32; H03K 3/36; H03K 3/57; H03K 17/56

(52) U.S. Cl. CPC H01J 37/32128; H01J 37/321; H01J 37/32183; H01J 37/32431; H03K 3/36; H03K 3/57; H03K 17/56

(57) ABSTRACT

Embodiments of the invention includes various power supplies for plasma systems. These power supplies, for example, closes a switch to connect and disconnect a current pathway to cause an application of an asymmetric periodic voltage waveform. Where each cycle of the asymmetric periodic voltage waveform includes a first portion that begins with a first negative voltage and changes to a positive peak voltage, a second portion that changes from the positive peak voltage to a third voltage level and a fourth portion that includes a negative voltage ramp from the third voltage level to a fourth voltage level.

### BACKGROUND

The semiconductor device fabrication process uses plasma processing at different stages to manufacture semiconductor devices. These semiconductor devices may include a processors, a memory, integrated circuits, and other types integrated circuits and devices. Various other process utilize plasma processing. Plasma processing involves energizing a gas mixture by imparting energy to the gas molecules by introducing RF (radio frequency) energy into the gas mixture. This gas mixture is typically contained in a vacuum chamber, referred to as a plasma chamber, and the RF energy is typically introduced into the plasma chamber through electrodes.

In a typical plasma process, the RF generator generates power at a radio frequency, which is broadly understood as being within the range of 3 kHz and 300 GHz, and this power is transmitted through RF cables and networks to the plasma chamber. In order to provide efficient transfer of power from the RF generator to the plasma chamber, an intermediary circuit is used to match the fixed impedance of the RF generator with the variable impedance of the plasma chamber. Such an intermediary circuit is commonly referred to as an RF impedance matching network, or more simply as a matching network.

### SUMMARY

Some embodiments of the invention include a plasma system. The plasma system includes a plasma chamber; an RF driver configured to drive bursts into the plasma chamber with an RF frequency; a nanosecond pulser configured to drive pulses into the plasma chamber with a pulse repetition frequency, the pulse repetition frequency being less than the RF frequency; a high pass filter disposed between the RF driver and the plasma chamber; and a low pass filter disposed between the nanosecond pulser and the plasma chamber.

In some embodiments, the high pass filter may include a capacitor. In some embodiments, the low pass filter may include an inductor. In some embodiments, the RF driver may comprise a nanosecond pulser.

Some embodiments of the invention include plasma system. The plasma system includes a plasma chamber may include a plurality of walls and a wafer support. When a plasma is created within the plasma chamber a wall-plasma sheath is formed between the plasma and the at least one of the plurality of walls, and a wafer-plasma sheath is formed between the plasma and a wafer disposed on the wafer support. The capacitance of the wall-plasma sheath is at least about ten times greater than the capacitance of the wafer-plasma sheath. An RF driver drives bursts into the plasma chamber with an RF frequency. A nanosecond pulser drives pulses into the plasma chamber with a pulse repetition frequency, the pulse repetition frequency being less than the RF frequency. A first filter disposed between the RF driver and the plasma chamber. A second filter disposed between the nanosecond pulser and the plasma chamber.

In some embodiments, the capacitance of the wafer-plasma sheath is less than about 1 nF. In some embodiments, the RF driver drives bursts with a peak voltage greater than about 1 kV and with a frequency greater than about 1 Mhz. In some embodiments, the nanosecond pulser drives pulses with a peak voltage greater than about 1 kV and with a frequency less than the frequency of the bursts produced by the RF generator. In some embodiments, the first filter comprises a high pass filter and wherein the second filter comprises a low pass filter. In some embodiments, the second filter comprises a capacitor coupled with ground. In some embodiments, the capacitor has a capacitance less than about 500 pF.

Some embodiments of the invention include plasma system. The plasma system includes a plasma chamber may include a plasma chamber; an RF driver electrically coupled with the plasma chamber that drives bursts into the plasma chamber with an RF frequency; a nanosecond pulser electrically coupled with the plasma chamber that drives pulses into the plasma chamber with a pulse repetition frequency, the pulse repetition frequency being less than the RF frequency; a capacitor disposed between the RF driver and the plasma chamber; and an inductor disposed between the nanosecond pulser and the plasma chamber.

In some embodiments, the capacitor has a capacitance less than about 100 pF. In some embodiments, the inductor has an inductance less than about 10 nH. In some embodiments, the inductor has a stray capacitance less than about 5 pF.

In some embodiments, the plasma chamber comprises a plurality of walls and a wafer support such that when a plasma is created within the plasma chamber a wall-plasma sheath is formed between the plasma and the at least one of the plurality of walls, and a wafer-plasma sheath is formed between the plasma and a wafer disposed on the wafer support, wherein the capacitance of the wall-plasma sheath is at least about ten times greater than the capacitance of the wafer-plasma sheath.

In some embodiments, the plasma chamber comprises a plurality of walls and a wafer support such that when a plasma is created within the plasma chamber a wall-plasma sheath is formed between the plasma and the at least one of the plurality of walls, and a wafer-plasma sheath is formed between the plasma and a wafer disposed on the wafer support, wherein the capacitance of the wall-plasma sheath is at least about fifty times greater than the capacitance of the wafer-plasma sheath.

Some embodiments of the invention include plasma system. The plasma system includes a plasma chamber may include a plasma chamber; an RF driver configured to drive pulses into the plasma chamber with an RF frequency greater than about 200 kHz and peak voltages greater than 1 kV; an energy sink circuit electrically coupled with the plasma chamber; a rectifying diode electrically couped between the plasma chamber and the RF driver such that the rectifying diode rectifies waveforms produced by the RF driver; and a droop control inductor and a droop resistance arranged in series such that the series combination of the droop control inductor and the droop control resistor are arranged in parallel with the rectifying diode.

In some embodiments, the energy sink circuit comprises a resistive output stage circuit. In some embodiments, the energy sink circuit comprises an energy recovery circuit. In some embodiments, the droop control inductor has an inductance less than about 10 mH. In some embodiments, the droop resistance is less than about 500Ω.

These embodiments are mentioned not to limit or define the disclosure, but to provide examples to aid understanding thereof. Additional embodiments are discussed in the Detailed Description, and further description is provided there. Advantages offered by one or more of the various embodiments may be further understood by examining this specification or by practicing one or more embodiments presented.

### BRIEF DESCRIPTION OF THE FIGURES

These and other features, aspects, and advantages of the present disclosure are better understood when the following Detailed Description is read with reference to the accompanying drawings.

FIG. 1A shows a pulse from a nanosecond pulser according to some embodiments.

FIG. 1B shows a bust of pulses from a nanosecond pulser according to some embodiments.

FIG. 2A shows a burst from an RF Driver according to some embodiments.

FIG. 2B shows a plurality of bursts from an RF Driver according to some embodiments.

FIG. 3 is a schematic representation of a plasma system according to some embodiments.

FIG. 4 is a schematic representation of a plasma system according to some embodiments.

FIG. 5 is a schematic representation of a plasma system according to some embodiments.

FIG. 6 is a schematic representation of a plasma system according to some embodiments.

FIG. 7 is an example circuit diagram of a filtered RF driver and a nanosecond pulser according to some embodiments.

FIG. 8 is an example circuit diagram of a filtered RF driver and a nanosecond pulser according to some embodiments.

FIG. 9 is an example circuit diagram of a filtered RF driver and a nanosecond pulser according to some embodiments.

FIG. 10 is an example circuit diagram of a filtered RF driver and a nanosecond pulser according to some embodiments.

FIG. 11 is an example circuit diagram of a filtered RF driver and a nanosecond pulser according to some embodiments.

FIG. 12 is an example circuit diagram of a filtered RF driver according to some embodiments.

FIG. 13 illustrates waveforms produced by an RF driver.

FIG. 14 illustrates waveforms produced by an RF driver.

FIG. 15 is an example circuit diagram of a filtered RF driver according to some embodiments.

FIG. 16 is a schematic representation of a planar RF plasma reactor according to some embodiments.

FIG. 17 is schematic of the equivalent electric circuit model of an RF plasma reactor according to some embodiments.

FIG. 18. illustrates calculated waveforms of the voltage Vᵣ across the plasma reactor and the plasma potential V_{P} for equal areas of the target and substrate electrodes.

FIG. 19 Illustrates calculated waveforms of the potential V_{ST} across the plasma sheath adjacent to the target electrode and that of the potential V_{SS} across the sub-strate electrode.

FIG. 20 is a block diagram of an RF Driver according to some embodiments.

FIG. 21 is a circuit diagram of an RF Driver according to some embodiments.

FIG. 22 is a waveform of the voltage across the transformer T1 (red), at the Pole (green), and at the wafer (blue) for a time frame of 600 μs.

FIG. 23 is a zoomed view of the waveform over a time frame of 10 μs.

FIG. 24 is a circuit diagram of an RF Driver according to some embodiments.

FIG. 25 is a circuit diagram of an RF Driver according to some embodiments.

FIG. 26 is a circuit diagram of an RF Driver according to some embodiments.

FIG. 27 is a circuit diagram of an RF Driver according to some embodiments.

FIG. 28 is a circuit diagram of an RF Driver according to some embodiments.

FIGS. 29A, 29B, 30A, and 30B are circuit diagrams of example resonant circuits.

FIG. 31 is a continuous waveform of the voltage across the transformer T1 (red), at the Pole (green), and at the wafer (blue).

FIG. 32 is a short burst waveform of the voltage across the transformer T1 (red), at the Pole (green), and at the wafer (blue).

FIG. 33 is a waveform showing a series of short bursts across the transformer T1 (red), at the Pole (green), and at the wafer (blue).

### DETAILED DESCRIPTION

A plasma system is disclosed. The plasma system includes a plasma chamber; an RF driver configured to drive RF bursts into the plasma chamber with an RF frequency; a nanosecond pulser configured to drive pulses into the plasma chamber with a pulse repetition frequency, the pulse repetition frequency being less than the RF frequency; a high pass filter disposed between the RF driver and the plasma chamber; and a low pass filter disposed between the nanosecond pulser and the plasma chamber.

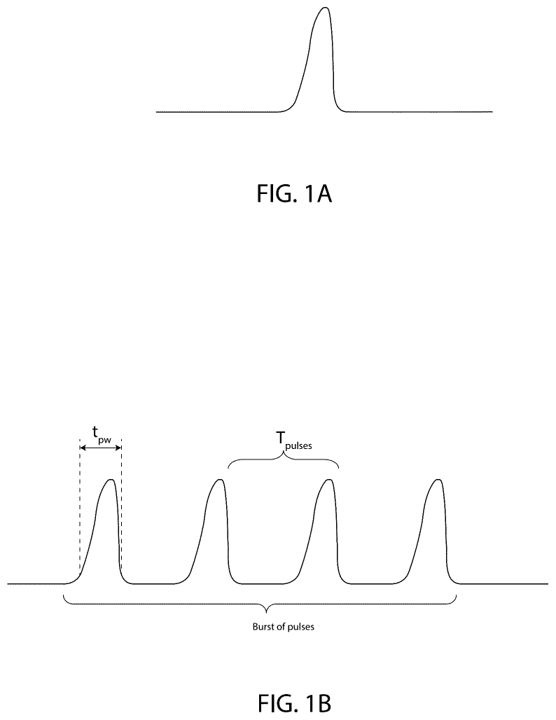

FIG. 1A shows an example pulse from a nanosecond pulser. FIG. 1B shows a burst of pulses from a nanosecond pulser. A burst may include a plurality of pulses within a short time frame. The burst from the nanosecond pulser can have a pulse repetition frequency of about 10 kHz, 50 Hz, 100 kHz, 500 kHz, 1 MHz, etc.

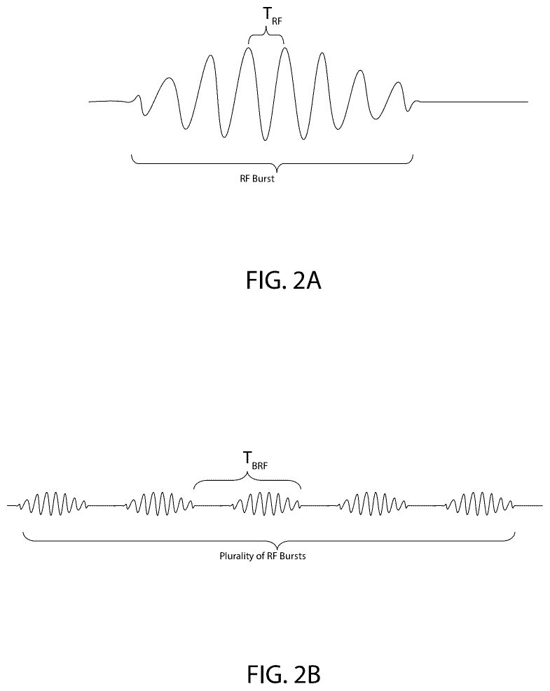

FIG. 2A shows an example burst from a RF driver according to some embodiments. FIG. 2B shows an example, plurality of bursts from an RF driver according to some embodiments. Each burst can include a sinusoidal burst with an RF frequency of 200 kHz and 800 MHz such as, for example, 2 MHz, 13.56 MHz, 27 MHz, 60 MHz, and 80 MHz. In some embodiments, the burst repetition frequency (e.g., the frequency of bursts) may be about 10 kHz, 50 Hz, 100 kHz, 500 kHz, 1 MHz, etc. such as, for example, 400 kHz. In some embodiments, the RF driver may provide a continuous sinusoidal burst.

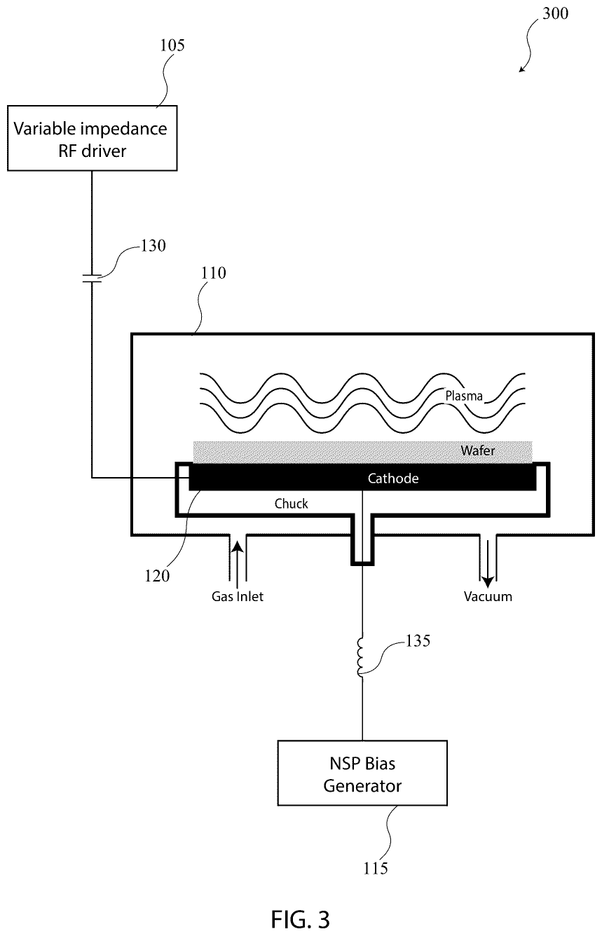

FIG. 3 is a schematic representation of a plasma system 300. In some embodiments, the plasma system 300 may include a plasma chamber 110 with a RF driver 105 and a nanosecond pulser 115 according to some embodiments. The RF driver 105 can be coupled with the electrode 120 located within the plasma chamber 110. The nanosecond pulser 115 can be coupled with the electrode 120 located inside or outside the plasma chamber 110. In some embodiments, the electrode 120 may be part of or coupled with an electrostatic chuck.

In some embodiments, the plasma chamber 110 may include a vacuum pump that maintains vacuum conditions in the plasma chamber 110. The vacuum pump, for example, may be connected to the plasma chamber 110 with a specialized hose or stainless steel piping. The vacuum pump may be controlled manually or automatically by a machine by either a relay or pass-through plug on the machine. In some embodiments, the plasma chamber 110 may be represented by an idealized or effective circuit for semiconductor processing chamber such as, for example, a plasma deposition system, semiconductor fabrication system, plasma sputtering system, etc.

In some embodiments, the plasma chamber 110 may include an input gas source that may introduce gas (or a mixture of input gases) into the chamber before, after, or when the RF power is supplied. The ions in the gas create the plasma and the gas is evacuated through the vacuum pump.

In some embodiments, the plasma system may include a plasma deposition system, plasma etch system, or plasma sputtering system. In some embodiments, the capacitance between the electrode (or chuck) and wafer may have a capacitance less than about 1000 nF, 500 nF, 200 nF, 100 nF, 50 nF, 10 nF, 5000 pF, 1000 pF, 100 pF, etc.

The RF driver 105 may include any type of device that generates RF power that is applied to the electrode 120. The RF driver 105, for example, may include a nanosecond pulser, a resonant system driven by a half bridge or full bridge circuit, an RF amplifier, a non-linear transmission line, an RF plasma generator, etc. In some embodiments, the RF driver 105 may include a match network.

In some embodiments, the RF driver 105 may include one or more RF drivers that may generate an RF power signal having a plurality of different RF frequencies such as, for example, 2 MHz, 13.56 MHZ, 27 MHz, 60 MHz, and 80 MHz. Typical RF frequencies, for example, may include frequencies between 200 kHz and 800 MHz In some embodiments, the RF driver 105 may create and sustain a plasma within the plasma chamber 110. The RF driver 105, for example, provides an RF signal to the electrode 120 (and/or the antenna 180, see below) to excite the various gases and/or ions within the chamber to create the plasma.

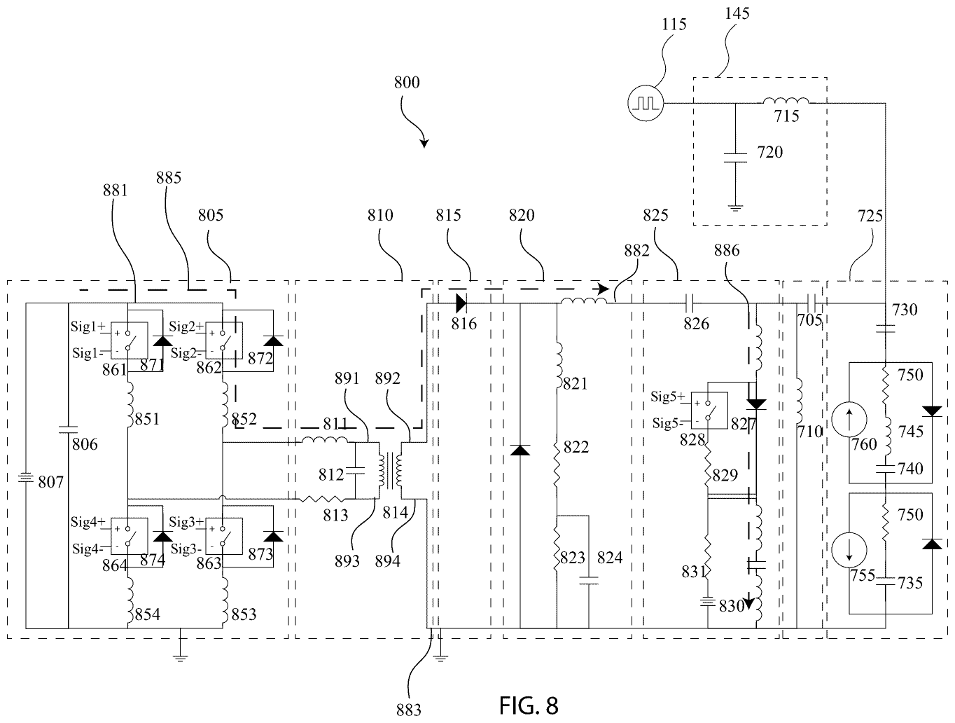

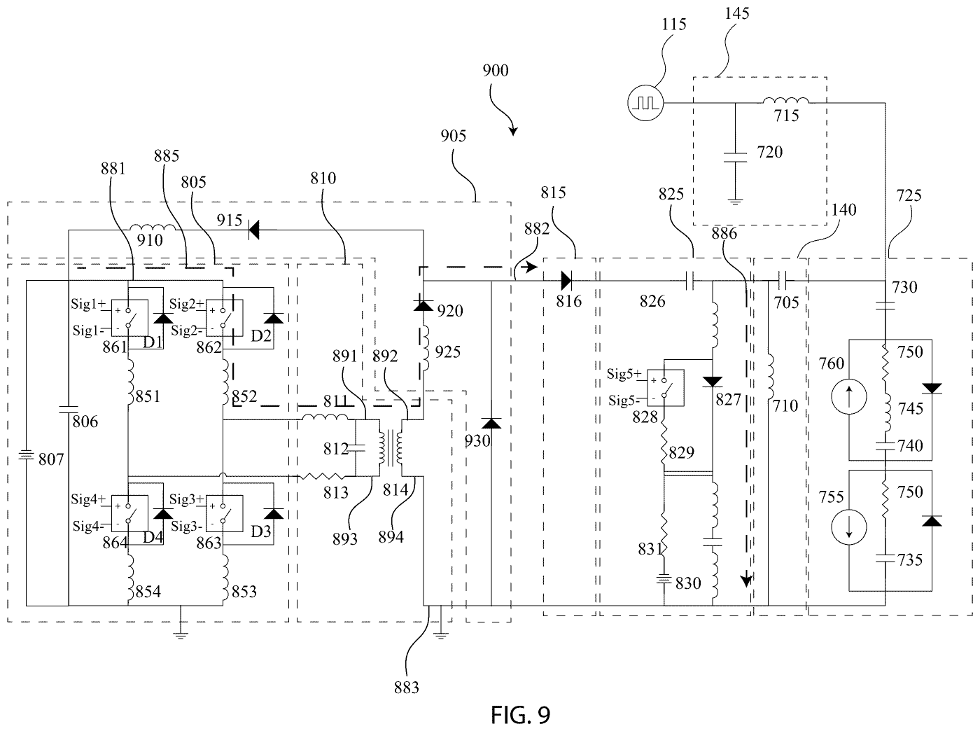

In some embodiments, the RF driver 105 may include any or all portions of the RF driver 800 shown in FIG. 8 and/or the RF driver 900 shown in FIG. 9.

In some embodiments, the RF driver 105 may be coupled with or may include an impedance matching circuit, which may match the output impedance of the RF driver 105 to the industry standard characteristic impedance of the coaxial cable of 50Ω or any cable.

The nanosecond pulser 115 may include one or more nanosecond pulsers. In some embodiments the nanosecond pulser 115 may include all or any portion of any device described in U.S. patent application Ser. No. 14/542,487, titled “High Voltage Nanosecond Pulser,” which is incorporated into this disclosure for all purposes, or all or any portion of any device described in U.S. patent application Ser. No. 14/635,991, titled “Galvanically Isolated Output Variable Pulse Generator Disclosure,” which is incorporated into this disclosure for all purposes, or all or any portion of any device described in U.S. patent application Ser. No. 14/798,154, titled “High Voltage Nanosecond Pulser With Variable Pulse Width and Pulse Repetition Frequency,” which is incorporated into this disclosure for all purposes, or all or any portion of any device described in U.S. patent application Ser. No. 16/697,173, titled “VARIABLE OUTPUT IMPEDANCE RF GENERATOR,” which is incorporated into this disclosure for all purposes.

The nanosecond pulser 115 may, for example, include the nanosecond pulser 1100 or the nanosecond pulser 1000.

In some embodiments, the nanosecond pulser 115 may pulse voltages with amplitudes of about 1 kV to about 40 kV. In some embodiments, the nanosecond pulser 115 may switch with a pulse repetition frequency up to about 2,000 kHz. In some embodiments, the nanosecond pulser may switch with a pulse repetition frequency of about 400 kHz. In some embodiments, the nanosecond pulser 115 may provide single pulses of varying pulse widths from about 2000 ns to about 1 nanosecond. In some embodiments, the nanosecond pulser 115 may switch with a pulse repetition frequency greater than about 10 kHz. In some embodiments, the nanosecond pulser 115 may operate with rise times less than about 400 ns on the load.

In some embodiments, the nanosecond pulser 115 can produce pulses from the power supply with voltages greater than 2 kV, with rise times less than about 400 ns on the load, and with a pulse repetition frequency greater than about 10 KHz.

In some embodiments, the nanosecond pulser 115 may include one or more solid state switches (e.g., solid state switches such as, for example, IGBTs, a MOSFETs, a SiC MOSFETs, SiC junction transistors, FETs, SiC switches, GaN switches, photoconductive switches, etc.), one or more snubber resistors, one or more snubber diodes, one or more snubber capacitors, and/or one or more freewheeling diodes. The one or more switches and or circuits can be arranged in parallel or series. In some embodiments, one or more nanosecond pulsers can be ganged together in series or parallel to form the nanosecond pulser 115. In some embodiments, a plurality of high voltage switches may be ganged together in series or parallel to form the nanosecond pulser 115.

In some embodiments, the nanosecond pulser 115 may include circuitry to remove charge from a capacitive load in fast time scales such as, for example, a resistive output stage, a sink, or an energy recovery circuit. In some embodiments, the charge removal circuitry may dissipate charge from the load, for example, on fast time scales (e.g., 1 ns, 10 ns, 50 ns, 100 ns, 250 ns, 500 ns, 1,000 ns, etc. time scales).

In some embodiments, a DC bias power supply stage may be included to bias the output voltage to the electrode 120 either positively or negatively. In some embodiments, a capacitor may be used to isolate/separate the DC bias voltage from the charge removal circuitry or other circuit elements. It may also allow for a potential shift from one portion of the circuit to another. In some applications the potential shift may be used to hold a wafer in place.

In some embodiments, the RF driver 105 may produce burst with an RF frequency greater than the pulse repetition frequency of the pulses produced by the nanosecond pulser 115.

In some embodiments, a capacitor 130 may be disposed (e.g., in series) between the RF driver 105 and the electrode 120. The capacitor 130 may be used, for example, to filter low frequency signals from the nanosecond pulser 115. These low frequency signals, for example, may have frequencies (e.g., the majority of spectral content) of about 100 kHz and 10 MHz such as, for example, about 10 MHz. The capacitor 130, for example, may have values of about 1 pF to 1 nF such as, for example, less than about 100 pF.

In some embodiments, an inductor 135 may disposed (e.g., in series) between the nanosecond pulser 115 and the electrode 120. The inductor 135 may be used, for example, to filter high frequency signals from the RF driver 105. These high frequency signals, for example, may have frequencies from about 1 MHz to 200 MHz such as, for example, greater than about 1 MHz or 10 MHz. The inductor 135, for example, may have values from about 10 nH to 10 pH such as, for example, greater than about 1 pH. In some embodiments, the inductor 135 may have a low coupling capacitance across it. In some embodiments, the coupling capacitance may be less than 1 nF

In some embodiments, either or both the capacitor 130 and the inductor 135 may isolate the pulses produce by the RF driver 105 from the pulses produce by the nanosecond pulser 115. For example, the capacitor 130 may isolate the pulses produced by the nanosecond pulser 115 from the pulses produced by the RF driver 105. The inductor 135 may isolate the pulses produced by the RF driver 105 from the pulses produced by the nanosecond pulser 115.

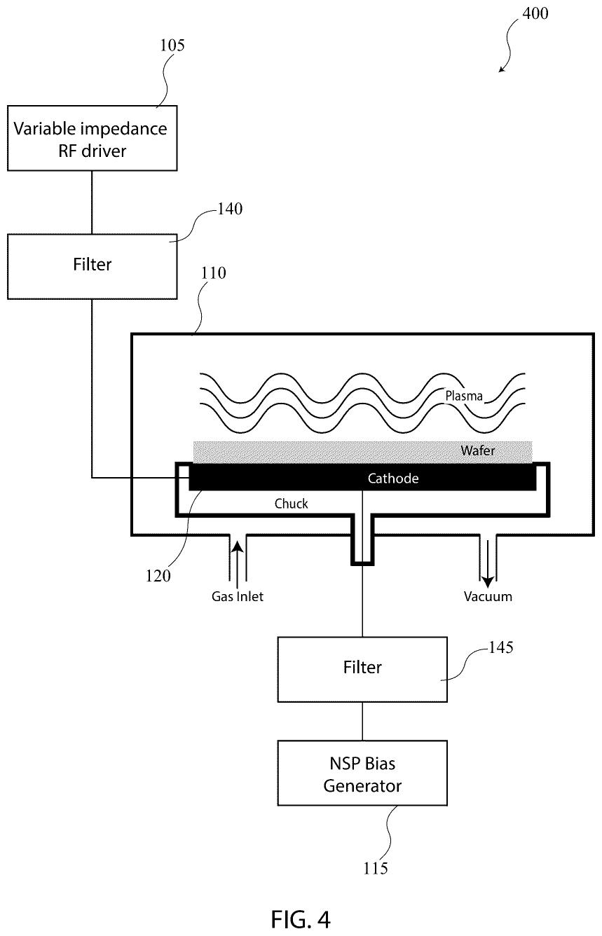

FIG. 4 is a schematic representation of a plasma system 400. Plasma system 400 includes plasma chamber 110 with the RF driver 105 and a filtered nanosecond pulser 115 according to some embodiments. Portions of the plasma system 400 may be similar to the plasma system 300 in FIG. 3. In this embodiment, a filter 140 may replace the capacitor 130 and/or the filter 145 may replace the inductor 135. The filters alternately protect the RF driver from the pulses produced by the NSP bias generator, and the nanosecond pulser from the RF produced by the RF driver. Numerous different filters may be employed to accomplish this.

In some embodiments, the RF driver 105 may produce bursts with an RF frequency, fₚ, greater than pulse repetition frequency in each burst produced by the nanosecond pulser 115.

In some embodiments, the filter 140 may be disposed (e.g., in series) between the RF driver 105 and the electrode 120. The filter 140 may be a high pass filter that allows high frequency pulses with frequencies from about 1 MHz to 200 MHz such as, for example, about 1 MHz or 10 MHz. The filter 140, for example, may include any type of filter that can pass these high frequency signals.

In some embodiments, the filter 145 may be disposed (e.g., in series) between the nanosecond pulser 115 and the electrode 120. The filter 145 may be a low pass filter that allows low frequency pulses with frequencies less than about 100 kHz and 10 MHz such as, for example, about 10 MHz. The filter 145, for example, may include any type of filter that can pass these low frequency signals.

In some embodiments, either or both the filter 140 and the filter 145 may isolate the pulses produce by the RF driver 105 from the pulses produce by the nanosecond pulser 115. For example, the filter 140 may isolate the pulses produced by the nanosecond pulser 115 from the pulses produced by the RF driver 105. The filter 145 may isolate the pulses produced by the RF driver 105 from the pulses produced by the nanosecond pulser 115.

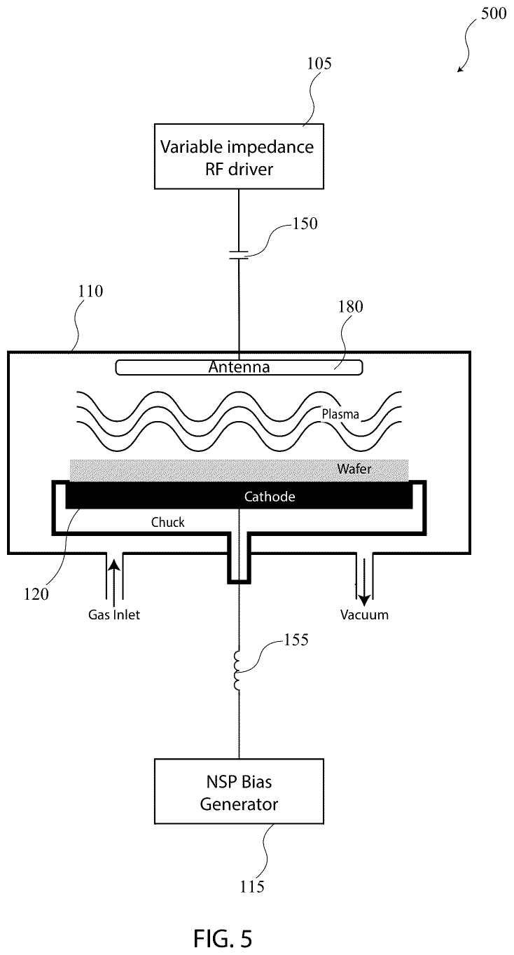

FIG. 5 is a schematic representation of a plasma system 500. The plasma system 500 may include a plasma chamber 110 with an RF driver 105 and a nanosecond pulser 115 according to some embodiments.

The RF driver 105 may include any type of device that generates RF power that is applied to the antenna 180. In some embodiments, the RF driver 105 may include one or more RF drivers that may generate an RF power signal having a plurality of different RF frequencies such as, for example, 2 MHz, 13.56 MHz, 27 MHz, and 60 MHz.

In some embodiments, the RF driver 105 may be coupled with or may include an impedance matching circuit, which may match the output impedance of the RF driver 105, which is typically 50Ω, to the variable impedance of the plasma load, which is typically much smaller and may be reactive.

In some embodiments, the RF driver 105 may include one or more nanosecond pulsers.

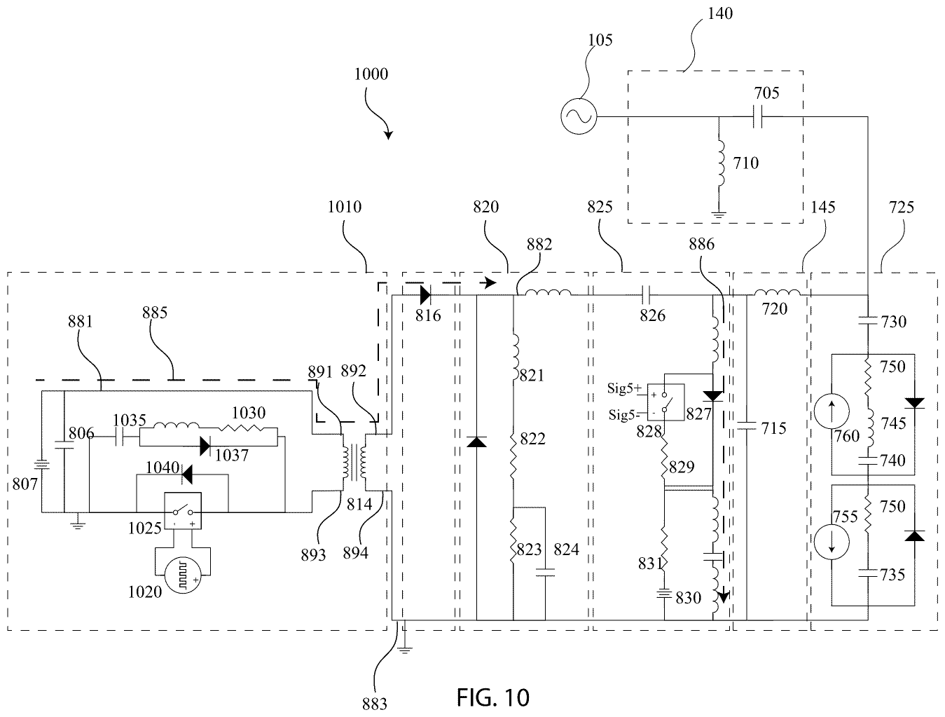

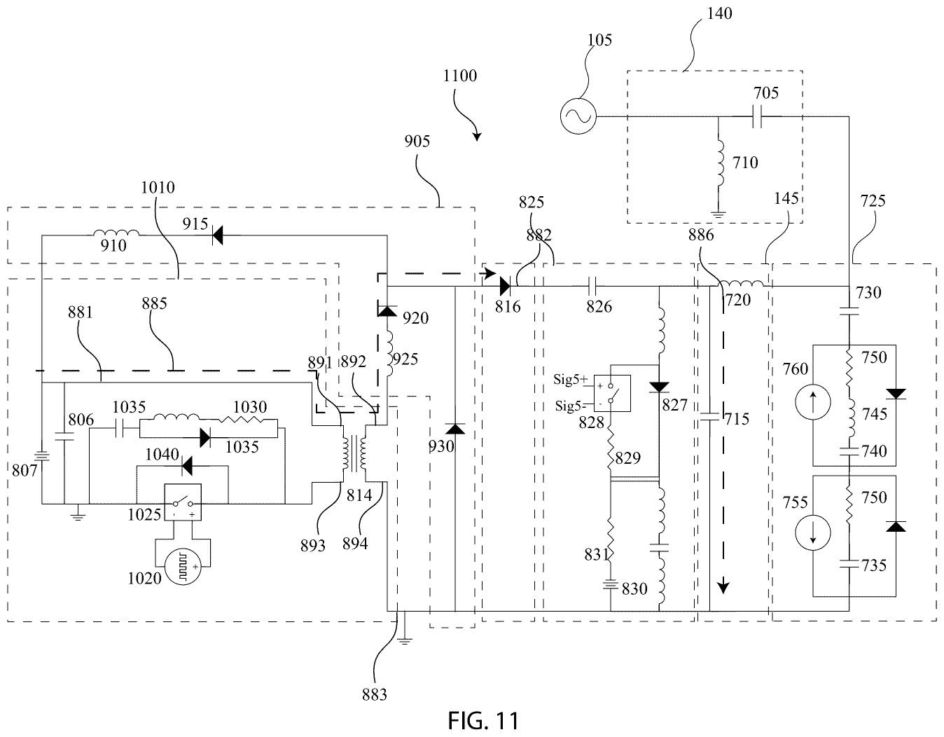

In some embodiments, the nanosecond pulser 115 is described in conjunction with FIG. 1. In some embodiments, the nanosecond pulser 1000 described in FIG. 10 or the nanosecond pulser 1100 described in FIG. 11.

In some embodiments, the RF driver 105 may produce pulses with an RF frequency greater than the pulse repetition frequency of the pulses produced by the nanosecond pulser 115.

In some embodiments, a capacitor 150 may be disposed (e.g., in series) between the RF driver 105 and the antenna 180. The capacitor 150 may be used, for example, to filter low frequency signals from the nanosecond pulser 115. These low frequency signals, for example, may have frequencies less than about 100 kHz and 10 MHz such as, for example, about 10 MHz. The capacitor 150, for example, may have values of about 1 pF to 1 nF such as, for example, less than about 100 pF.

In some embodiments, an inductor 155 may disposed (e.g., in series) between the nanosecond pulser 115 and the electrode 120. The inductor 135 may be used, for example, to filter high frequency signals from the RF driver 105. These high frequency signals, for example, may have frequencies greater than about 1 MHz to 200 MHz such as, for example, greater than about 1 MHz or 10 MHz. The inductor 155, for example, may have values less than about 10 nH to 10 μH such as, for example, greater than about 1 μH. In some embodiments, the inductor 155 may have a low coupling capacitance across it.

In some embodiments, either or both the capacitor 150 and the inductor 155 may isolate the pulses produce by the RF driver 105 from the pulses produce by the nanosecond pulser 115. For example, the capacitor 150 may isolate the pulses produced by the nanosecond pulser 115 from the pulses produced by the RF driver 105. The inductor 155 may isolate the pulses produced by the RF driver 105 from the pulses produced by the nanosecond pulser 115.

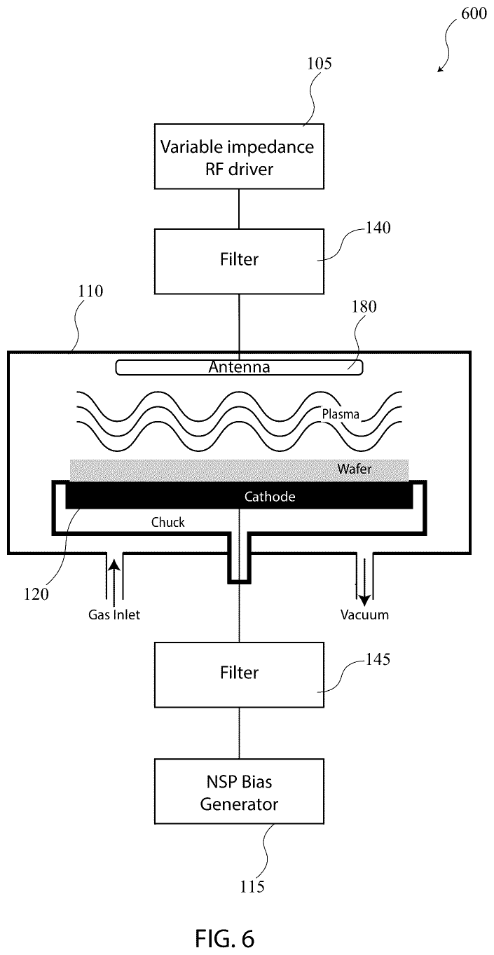

FIG. 6 is a schematic representation of a plasma system 600 with an RF driver 105 and a nanosecond pulser 115 according to some embodiments. The RF driver 105 may include any type of RF driver. Portions of the plasma system 600 may be similar to the plasma system 500 in FIG. 5. A filter 140 may replace the capacitor 150 and/or the filter 145 may replace the inductor 135 used in FIG. 5.

The plasma system 600 includes a plasma chamber 725. The RF driver 105 and/or the nanosecond pulser 115 produce bursts and/or pulses that drive a plasm within the plasma chamber 725. The plasma chamber 725 is an idealized and/or effective circuit representation of a plasma and a plasma chamber.

In some embodiments, the RF driver 105 may produce bursts with an RF frequency greater than the pulse repetition frequency of the pulses produced by the nanosecond pulser 115.

In some embodiments, the filter 140 may be disposed (e.g., in series) between the RF driver 105 and the electrode 120. The filter 140 may be a high pass filter that allows high frequency pulses with frequencies greater than about 1 MHz to 200 MHz such as, for example, greater than about 1 MHz or 10 MHz. The filter 140, for example, may include any type of filter that can pass these high frequency signals.

In some embodiments, the filter 145 may be disposed (e.g., in series) between the nanosecond pulser 115 and the electrode 120. The filter 145 may be a low pass filter that allows low frequency pulses with frequencies less than about 100 kHz and 10 MHz such as, for example, about 10 MHz. The filter 145, for example, may include any type of filter that can pass these low frequency signals.

In some embodiments, either or both the filter 140 and the filter 145 may isolate the pulses produce by the RF driver 105 from the pulses produce by the nanosecond pulser 115 and/or vice versa. For example, the filter 140 may isolate the pulses produced by the nanosecond pulser 115 from the pulses produced by the RF driver 105. The filter 145 may isolate the pulses produced by the RF driver 105 from the pulses produced by the nanosecond pulser 115.

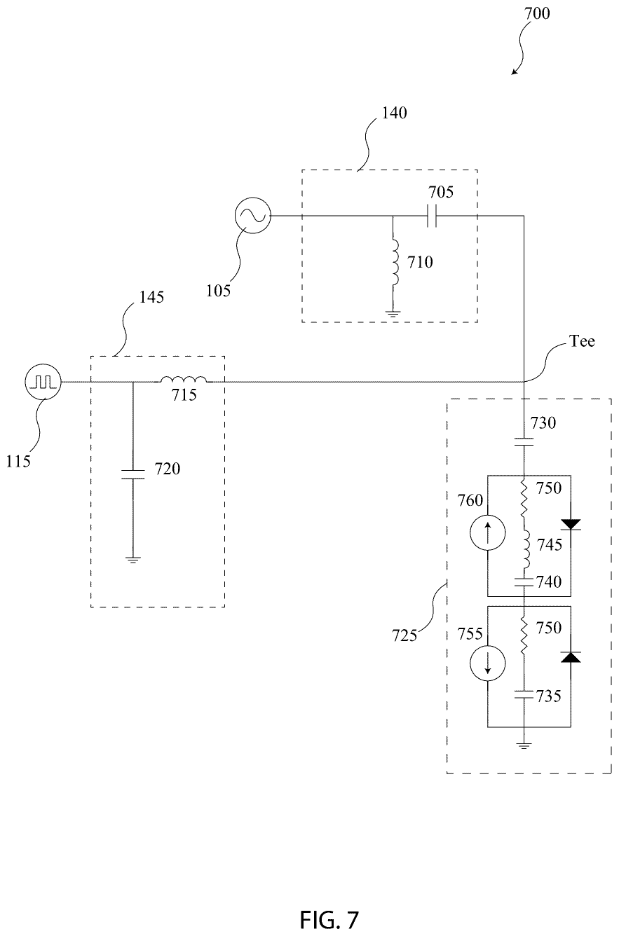

FIG. 7 is an example circuit diagram 700 of a RF driver 105 and a nanosecond pulser 115 driving a plasma within the plasma chamber 725 according to some embodiments. In some embodiments, the RF driver 105 may operate at a frequency of about 60 MHz.

In some embodiments, the impedance filter 140 may also serve as a high pass filter that protects the RF driver 105 from the output of the nanosecond pulser 720. For example, capacitor 720 may filter the output of the nanosecond pulser 720. The RF driver 105, for example, may operate at frequencies greater than 1 MHz, 10 MHz, 100 MHZ, 1,000 MHz, etc. The impedance matching network, for example, may include any type of impedance matching networks that can serve as a high pass filter. In some embodiments, the impedance matching network may also serve as a high pass filter (e.g., filter 140) such as, for example, when it includes a series capacitance that is less than 10 nF, 1 nF, 100 pF, 10 pF, 1 pF.

The plasma chamber 110 may be represented by a number of equivalent circuit elements shown within an effective (or idealized) plasma chamber 725.

In some embodiments, the plasma chamber 725 may be represented by an idealized or effective circuit for semiconductor processing chamber such as, for example, a plasma deposition system, semiconductor fabrication system, plasma sputtering system, etc. The capacitor 730, for example, may represent the capacitance of a chuck upon which a wafer may sit. The chuck, for example, may comprise a dielectric material. For example, the capacitor 730 may have small capacitance (e.g., about 10 pF, 100 pF, 500 pF, 1 nF, 10 nF, 100 nF, etc.).

A plasma sheath may form within the plasma chamber that may include a non-neutral region to balance electron and ion losses. The wafer-sheath capacitor 740 represents the capacitance of the plasma sheath, which may be formed between the plasma and the top surface of the wafer. The resistor 750, for example, may represent the sheath resistance of the plasma and the wafer. The inductor 745, for example, may represent the sheath inductance between the plasma and the wafer. The current source 760, for example, may be represent the ion current through the sheath. For example, the wafer-sheath capacitor 740 may have small capacitance (e.g., about 10 pF, 100 pF, 500 pF, 1 nF, 10 nF, 100 nF, etc.).

The wall-sheath capacitor 735 represents the capacitance of the wall sheath, which may form between the plasma and one or more of the walls of the plasma chamber. The resistor 750, for example, may represent the resistance between the plasma of a processing chamber wall and the plasma. The current source 755, for example, may be representative of the ion current in the plasma. For example, the wall-sheath capacitance C1 (e.g., capacitance of wall-sheath capacitor 735) may have small capacitance (e.g., about 10 pF, 100 pF, 500 pF, 1 nF, 10 nF, 100 nF, etc.).

Various other plasma sheaths may be formed between the portions of the chamber or electrodes and the plasma.

A sheath capacitance can be estimated from the Child-Langmuir sheath. The Child-Langmuir sheath can be calculated from:

$$\frac{s}{{λ}_{D}} = \frac{0.32}{\sqrt{{α}_{e}}} {( \frac{{eV}_{0}}{{T}_{e}} )}^{3 / 4}$$

where λ_{D} is the Debye length, s is the sheath length, Tₑ is the electron temperature, −V₀ is the bias voltage on the boundary, and αₑ is the electron density reduction factor at the sheath edge. The sheath capacitance can then be calculated from:

$$C = \frac{{ε}_{0} A}{s} ,$$

where A is the area of the sheath boundary, and ε₀ is the permittivity of free space.

In some embodiments, the wall-sheath capacitance C1 (e.g., the capacitance of capacitor 735) may be larger than the wafer-sheath capacitance C3 (e.g., the capacitance of capacitor 740) ((C1>C3). For example, the ratio of the wall-sheath capacitance C1 divided by the wafer-sheath capacitance C3 may be greater than ten

$$( \frac{C 1}{C 3} > 10 ) .$$

As another example, the wall-sheath capacitance C1 shall be ten times the wafer-sheath capacitance C3 (C1>10*C3).

As another example, the ratio of the wall-sheath capacitance C1 divided by the sheath capacitance C3 may be greater than fifty

$$( \frac{C 1}{C 3} > 50 ) .$$

As another example, the wall-sheath capacitance C1 shall be fifty times the sheath capacitance C3 (C1>50*C3).

The RF driver 105 may include any type of device that generates RF power that is applied to the electrode in the plasma chamber 725. The RF driver 105, for example, may include a nanosecond pulser, a resonant system driven by a half bridge or full bridge circuit, an RF amplifier, a non-linear transmission line, an RF plasma generator, etc.

In some embodiments, the RF driver 105 may include one or more RF drivers that may generate an RF power signal having a plurality of different RF frequencies such as, for example, 2 MHZ, 13.56 MHZ, 27 MHz, 60 MHz, 80 MHz, etc. Typical RF frequencies, for example, may include frequencies between 200 kHz and 800 MHz In some embodiments, the RF driver 105 may create and sustain a plasma within the plasma chamber 725. The RF driver 105, for example, may provide an RF signal to the electrode (and/or the antenna, see below) to excite the various gases and/or ions within the chamber to create the plasma.

In some embodiments, the RF driver 105 may be coupled with or may include a matching network, which may match the output impedance of the RF driver 105, which is typically 50Ω, to the variable impedance of the plasma load, which is typically much smaller and may be reactive.

The nanosecond pulser 720 may include one or more nanosecond pulsers. In some embodiments the nanosecond pulser 720 may include all or any portion of any device described in U.S. patent application Ser. No. 14/542,487, titled “High Voltage Nanosecond Pulser,” which is incorporated into this disclosure for all purposes, or all or any portion of any device described in U.S. patent application Ser. No. 14/635,991, titled “Galvanically Isolated Output Variable Pulse Generator Disclosure,” which is incorporated into this disclosure for all purposes, or all or any portion of any device described in U.S. patent application Ser. No. 14/798,154, titled “High Voltage Nanosecond Pulser With Variable Pulse Width and Pulse Repetition Frequency,” which is incorporated into this disclosure for all purposes.

In some embodiments, the nanosecond pulser 720 may pulse voltages with amplitudes of about 1 kV to about 40 kV. In some embodiments, the nanosecond pulser 720 may switch with a pulse repetition frequency up to about 2,000 kHz. In some embodiments, the nanosecond pulser may switch with a pulse repetition frequency of about 400 kHz. In some embodiments, the nanosecond pulser 720 may provide single pulses of varying pulse widths from about 2000 ns to about 1 nanosecond. In some embodiments, the nanosecond pulser 720 may switch with a pulse repetition frequency greater than about 10 kHz. In some embodiments, the nanosecond pulser 720 may operate with rise times less than about 400 ns on the load.

In some embodiments, the nanosecond pulser 720 can produce pulses from the power supply with voltages greater than 2 kV, with rise times less than about 80 ns, and with a pulse repetition frequency greater than about 10 KHz.

In some embodiments, the nanosecond pulser 720 may include one or more solid state switches (e.g., solid state switches such as, for example, IGBTs, a MOSFETs, a SiC MOSFETs, SiC junction transistors, FETs, SiC switches, GaN switches, photoconductive switches, etc.), one or more snubber resistors, one or more snubber diodes, one or more snubber capacitors, and/or one or more freewheeling diodes. The one or more switches and or circuits can be arranged in parallel or series. In some embodiments, one or more nanosecond pulsers can be ganged together in series or parallel to form the nanosecond pulser 720. In some embodiments, a plurality of high voltage switches may be ganged together in series or parallel to form the nanosecond pulser 720.

In some embodiments, the nanosecond pulser 720 may include circuitry to remove charge from a capacitive load in fast time scales such as, for example, a resistive output stage, a sink, or an energy recovery circuit. In some embodiments, the charge removal circuitry may dissipate charge from the load, for example, on fast time scales (e.g., 1 ns, 10 ns, 50 ns, 100 ns, 250 ns, 500 ns, 1,000 ns, etc. time scales).

FIG. 8 is a circuit diagram of an example RF driver 800 driving a plasma within the plasma chamber 725 according to some embodiments. In this example, the RF driver 800 is one example of an RF driver 105. The RF driver 800 may be coupled with the nanosecond pulser 115 and the filter 145.

In this example, the RF driver 800 may include an RF source 805, a resonant circuit 810, a half-wave rectifier 815, a resistive output stage 820, and/or a bias compensation circuit 825. The RF source 805 may be a full-bridge driver (or half-bridge driver). The RF source 805 may include an input voltage source 807 that may be a DC voltage source (e.g., a capacitive source, AC-DC converter, etc.). In some embodiments, the RF source 805 may include four switches 861, 862, 863, 864. In some embodiments, the RF source 805 may include a plurality of switches 861, 862, 863, and 864 in series or in parallel. These switches 861, 862, 863, 864, for example, may include any type of solid-state switch such as, for example, IGBTs, a MOSFETs, a SiC MOSFETs, SiC junction transistors, FETs, SiC switches, GaN switches, photoconductive switches, etc. These switches 861, 862, 863, and 864 may be switched at high frequencies and/or may produce a high voltage pulses. These frequencies may, for example, include frequencies of about 400 kHz, 0.5 MHz, 2.0 MHz, 4.0 MHz, 13.56 MHz, 27.12 MHz, 40.68 MHz, 50 MHz, etc.

Each switch of switches 861, 862, 863, 864 may be coupled in parallel with a respective diode 871, 872, 873, and/or 874 and may include stray inductance represented by inductor 851, 852, 853, and 854. In some embodiments, the inductances of inductor 851, 852, 853, and 854 may be equal. In some embodiments, the inductances of inductor 851, 852, 853, and 854 may be less than about 50 nH, 100 nH, 150 nH, 500 nH, 1,000 nH, etc. The combination of a switch (861, 862, 863, or 864) and a respective diode (871, 872, 873, and/or 874) may be coupled in series with a respective inductor (851, 852, 853, or 854). Inductors 853 and 854 are connected with ground. Inductor 851 is connected with switch 864 and the resonant circuit 810. And inductor 852 is connected with switch 863 and the opposite side of the resonant circuit 810.

In some embodiments, the RF source 805 may be coupled with a resonant circuit 810. The resonant circuit 810 may include a resonant inductor 811 and/or a resonant capacitor 812 coupled with a transformer 814. The resonant circuit 810 may include a resonant resistor 813, for example, that may include the stray resistance of any leads between the RF source 805 and the resonant circuit 810 and/or any component within the resonant circuit 810 such as, for example, the resonant capacitor 812, the resonant resistor 813, and/or the resonant inductor 811. In some embodiments, the resonant resistor 813 may comprise only stray resistances of wires, traces, or circuit elements. While the inductance and/or capacitance of other circuit elements may affect the driving frequency, the driving frequency can be set largely by choice of the resonant inductor 811 and/or the resonant capacitor 812. Further refinements and/or tuning may be required to create the proper driving frequency in light of stray inductance or stray capacitance. In addition, the rise time across the transformer 814 can be adjusted by changing resonant inductor 811 (L) and/or resonant capacitor 812 (C), provided that:

$${f}_{resonant} = \frac{1}{2 π \sqrt{( L ) ( C )}} = constant .$$

In some embodiments, large inductance values for resonant inductor 811 can result in slower or shorter rise times. These values may also affect the burst envelope. Each burst can include transient and steady state pulses. The transient pulses within each burst may be set by resonant inductor 811 and/or the Q of the system until full voltage is reached during the steady state pulses.

If the switches in the RF source 805 are switched at the resonant frequency, fᵣₑₛₒₙₐₙₜ, then the output voltage at the transformer 814 will be amplified. In some embodiments, the resonant frequency may be about 400 kHz, 0.5 MHz, 2.0 MHz, 4.0 MHz, 13.56 MHz, 27.12 MHz, 40.68 MHz, 50 MHz, etc.

In some embodiments, the resonant capacitor may include the stray capacitance of the transformer 814 and/or a physical capacitor. In some embodiments, the resonant capacitor may have a capacitance of about 10 μF, 1 μF, 100 nF, 10 nF, etc. In some embodiments, the resonant inductor 811 may include the stray inductance of the transformer 814 and/or a physical inductor. In some embodiments, the resonant inductor 811 may have an inductance of about 50 nH, 100 nH, 150 nH, 500 nH, 1,000 nH, etc. In some embodiments, the resonant resistor 813 may have a resistance of about 10Ω, 25Ω, 50Ω, 100Ω, 150Ω, 500Ω, etc.

In some embodiments, the transformer 814 may be optional. In some embodiments, one or more of resistor 813, resonant inductor 811, and/or resonant capacitor 812 may be disposed on the secondary side of the transformer 814.

In some embodiments, the resonant resistor 813 may represent the stray resistance of wires, traces, and/or the transformer windings within the physical circuit. In some embodiments, the resonant resistor 813 may have a resistance of about 10 mΩ, 50 mΩ, 100 mΩ, 200 mΩ, 500 mΩ, etc.

In some embodiments, the transformer 814 may comprise a transformer as disclosed in U.S. patent application Ser. No. 15/365,094, titled “High Voltage Transformer,” which is incorporated into this document for all purposes. In some embodiments, the output voltage of the resonant circuit 810 can be changed by changing the duty cycle (e.g., the switch “on” time or the time a switch is conducting) of switches 861, 862, 863, and/or 864. For example, the longer the duty cycle, the higher the output voltage; and the shorter the duty cycle, the lower the output voltage. In some embodiments, the output voltage of the resonant circuit 810 can be changed or tuned by adjusting the duty cycle of the switching in the RF source 805.

For example, the duty cycle of the switches can be adjusted by changing the duty cycle of signal Sig1, which opens and closes switch 861; changing the duty cycle of signal Sig2, which opens and closes switch 862; changing the duty cycle of signal Sig3, which opens and closes switch 863; and changing the duty cycle of signal Sig4, which opens and closes switch 864. By adjusting the duty cycle of the switches 861, 862, 863, or 864, for example, the output voltage of the resonant circuit 810 or the voltage on the load can be controlled in real time.

In some embodiments, each switch 861, 862, 863, or 864 in the RF source 805 can be switched independently or in conjunction with one or more of the other switches. For example, the signal Sig1 may be the same signal as signal Sig3. As another example, the signal Sig2 may be the same signal as signal Sig4. As another example, each signal may be independent and may control each switch 861, 862, 863, or 864 independently or separately.

In some embodiments, the resonant circuit 810 may be coupled with a half-wave rectifier 815 that may include a rectifying diode 816.

In some embodiments, the half-wave rectifier 815 may be coupled with the resistive output stage 820. The resistive output stage 820 may include any resistive output stage known in the art. For example, the resistive output stage 820 may include any resistive output stage described in U.S. patent application Ser. No. 16/178,538 titled “HIGH VOLTAGE RESISTIVE OUTPUT STAGE CIRCUIT,” which is incorporated into this disclosure in its entirety for all purposes.

For example, the resistive output stage 820 may include an inductor 821, resistor 822, resistor 823, and capacitor 824. In some embodiments, inductor 821 may include an inductance of about 5 μH to about 25 μH. In some embodiments, the resistor 823 may include a resistance of about 50Ω to about 250Ω. In some embodiments, the resistor 822 may comprise the stray resistance in the resistive output stage 820.

In some embodiments, the resistor 823 may include a plurality of resistors arranged in series and/or parallel. The capacitor 824 may represent the stray capacitance of the resistor 823 including the capacitance of the arrangement series and/or parallel resistors. The capacitance of stray capacitor 824, for example, may be less than 500 pF, 250 pF, 100 pF, 50 pF, 10 pF, 1 pF, etc. The capacitance of stray capacitor 824, for example, may be less than the load capacitance such as, for example, less than the capacitance of capacitor 735, capacitor 730, and/or capacitor 740.

In some embodiments, the resistor 823 may discharge the load (e.g., a plasma sheath capacitance). In some embodiments, the resistive output stage 820 may be configured to discharge over about 1 kilowatt of average power during each pulse cycle and/or a joule or less of energy in each pulse cycle. In some embodiments, the resistance of the resistor 823 in the resistive output stage 820 may be less than 200Ω. In some embodiments, the resistor 823 may comprise a plurality of resistors arranged in series or parallel having a combined capacitance less than about 200 pF (e.g., capacitor 824).

In some embodiments, the resistive output stage 820 may include a collection of circuit elements that can be used to control the shape of a voltage waveform on a load. In some embodiments, the resistive output stage 820 may include passive elements only (e.g., resistors, capacitors, inductors, etc.). In some embodiments, the resistive output stage 820 may include active circuit elements (e.g., switches) as well as passive circuit elements. In some embodiments, the resistive output stage 820, for example, can be used to control the voltage rise time of a waveform and/or the voltage fall time of waveform.

In some embodiments, the resistive output stage 820 can discharge capacitive loads (e.g., a wafer and/or a plasma). For example, these capacitive loads may have small capacitance (e.g., about 10 pF, 100 pF, 500 pF, 1 nF, 10 nF, 100 nF, etc.).

In some embodiments, a resistive output stage can be used in circuits with pulses having a high pulse voltage (e.g., voltages greater than 1 kV, 10 kV, 20 kV, 50 kV, 100 kV, etc.) and/or high frequencies (e.g., frequencies greater than 1 kHz, 10 kHz, 100 kHz, 200 kHz, 500 kHz, 1 MHz, etc.) and/or frequencies of about 400 kHz, 0.5 MHz, 2.0 MHz, 4.0 MHz, 13.56 MHz, 27.12 MHz, 40.68 MHz, 50 MHz, etc.

In some embodiments, the resistive output stage may be selected to handle high average power, high peak power, fast rise times and/or fast fall times. For example, the average power rating might be greater than about 0.5 kW, 1.0 kW, 10 KW, 25 KW, etc., and/or the peak power rating might be greater than about 1 kW, 10 kW, 100 KW, 1 MW, etc.

In some embodiments, the resistive output stage 820 may include a series or parallel network of passive components. For example, the resistive output stage 820 may include a series of a resistor, a capacitor, and an inductor. As another example, the resistive output stage 820 may include a capacitor in parallel with an inductor and the capacitor-inductor combination in series with a resistor. For example, inductor 821 can be chosen large enough so that there is no significant energy injected into the resistive output stage when there is voltage out of the rectifier. The values of resistor 822 and resistor 823 can be chosen so that the L/R time can drain the appropriate capacitors in the load faster than the RF frequency

In some embodiments, the resistive output stage 820 may be coupled with the bias compensation circuit 825. The bias compensation circuit 825 may include any bias and/or bias compensation circuit known in the art. For example, the bias compensation circuit 825 may include any bias and/or bias compensation circuit described in U.S. patent application Ser. No. 16/523,840 titled “NANOSECOND PULSER BIAS COMPENSATION,” which is incorporated into this disclosure in its entirety for all purposes. In some embodiments, the resistive output stage 820 and/or the bias compensation circuit 825 may be optional.

In some embodiments, a nanosecond pulser may include a resistive output stage that is similar to the resistive output stage 820.

In some embodiments, the bias compensation circuit 825 may include a bias capacitor 826, blocking capacitor 826, a blocking diode 827, switch 828 (e.g., a high voltage switch), offset supply voltage 830, resistance 831, and/or resistance 829. In some embodiments, the switch 828 comprises a high voltage switch described in U.S. patent application Ser. No. 82/717,637, titled “HIGH VOLTAGE SWITCH FOR NANOSECOND PULSING,” and/or in U.S. patent application Ser. No. 16/178,565, titled “HIGH VOLTAGE SWITCH FOR NANOSECOND PULSING,” which is incorporated into this disclosure in its entirety for all purposes.

In some embodiments, the offset supply voltage 830 may include a DC voltage source that can bias the output voltage either positively or negatively. In some embodiments, the blocking capacitor 826 may isolate/separate the offset supply voltage 830 from the resistive output stage 820 and/or other circuit elements. In some embodiments, the bias compensation circuit 825 may allow for a potential shift of power from one portion of the circuit to another. In some embodiments, the bias compensation circuit 825 may be used to hold a wafer in place as high voltage pulses are active within the chamber. Resistance 831 may protect/isolate the DC bias supply from the driver.

In some embodiments, the switch 828 may be open while the RF source 805 is pulsing and closed when the RF source 805 is not pulsing. While closed, the switch 828 may, for example, short current across the blocking diode 827. Shorting this current may allow the bias between the wafer and the chuck to be less than 2 kV, which may be within acceptable tolerances.

FIG. 9 is a circuit diagram of an RF driver circuit 900 driving a plasma within the plasma chamber 725 according to some embodiments. In this example, the RF driver 900 is one example of an RF driver 105. The RF driver circuit 900 may be coupled with the nanosecond pulser 115 and the filter 145.

In this example, the RF driver circuit 900 may include an RF source 805, a resonant circuit 810, a half-wave rectifier 815, an energy recovery circuit 905, and/or a bias compensation circuit 825. The RF source 805 may be a full-bridge driver (or half-bridge driver).

The RF driver 900 is similar to the RF driver 800 with the resistive output stage 820 is replaced with an energy recovery circuit 905. The resistive output stage 820 and the energy recovery circuit 905 can be referred to as an energy sink circuit. In some embodiments, the energy recovery circuit 905 and/or the bias compensation circuit 825 may be optional.

In this example, the energy recovery circuit 905 may be positioned on or electrically coupled with the secondary side of the transformer 814. The energy recovery circuit 905, for example, may include a diode 930 (e.g., a crowbar diode) across the secondary side of the transformer 814. The energy recovery circuit 905, for example, may include diode 915 and inductor 910 (arranged in series), which can allow current to flow from the secondary side of the transformer 814 to charge the power supply 806 and current to flow to the plasma chamber 725. The diode 915 and the inductor 910 may be electrically connected with the secondary side of the transformer 814 and coupled with the power supply 806. The diode 915 and the inductor 910 may be In some embodiments, the energy recovery circuit 905 may include diode 920 and/or inductor 925 electrically coupled with the secondary of the transformer 814. The inductor 910 may represent the stray inductance and/or may include the stray inductance of the transformer 814.

When the pulser stage 1010 is turned on (pulsing), current may charge the plasma chamber 725 (e.g., charge the capacitor 735, capacitor 730, or capacitor 740). Some current, for example, may flow through inductor 910 when the voltage on the secondary side of the transformer 814 rises above the charge voltage on the power supply 806. When the nanosecond pulser is turned off, current may flow from the capacitors within the plasma chamber 725 through the inductor 910 to charge the power supply 806 until the voltage across the inductor 910 is zero. The diode 930 may prevent the capacitors within the plasma chamber 725 from ringing with the inductance in the plasma chamber 725 or the bias compensation circuit 825.

The diode 915 may, for example, prevent charge from flowing from the power supply 806 to the capacitors within the plasma chamber 725.

The value of inductor 910 can be selected to control the current fall time. In some embodiments, the inductor 910 can have an inductance value between 1 μH-500 μH.

In some embodiments, the energy recovery circuit 905 may include a switch that can be used to control the flow of current through the inductor 910. The switch, for example, may be placed in series with the inductor 910

A switch in the energy recovery circuit 905, for example, may include a high voltage switch such as, for example, the high voltage switch disclosed in U.S. patent application Ser. No. 16/178,565 filed Nov. 1, 2018, titled “HIGH VOLTAGE SWITCH WITH ISOLATED POWER,” which claims priority to U.S. Provisional Patent Application No. 62/717,637 filed Aug. 10, 2018, both of which are incorporated by reference in the entirety. In some embodiments, the RF source 805 may include a high voltage switch in place of or in addition to the various components shown in RF source 805.

FIG. 10 is a circuit diagram of a nanosecond pulser 1000 driving a plasma within the plasma chamber 725 according to some embodiments. In this example, the nanosecond pulser 1000 is one example of a nanosecond pulser 115. The nanosecond pulser 1000 may be coupled with the RF driver 105 and the filter 140. In this example, the nanosecond pulser 1000 may include pulser stage 1010, a resistive output stage 820, and/or a bias compensation circuit 825.

In some embodiments, the nanosecond pulser 1000 (or the pulser stage 1010) can introduce pulses into the load stage with voltages greater than 1 kV, 10 kV, 20 kV, 50 kV, 100 kV, 1,000 kV, etc., with rise times less than about 1 ns, 10 ns, 50 ns, 100 ns, 250 ns, 500 ns, 1,000 ns, etc. with fall times less than about 1 ns, 10 ns, 50 ns, 100 ns, 250 ns, 500 ns, 1,000 ns, etc. and frequencies greater than about 1 kHz, 10 kHz, 100 kHz, 200 kHz, 500 kHz, 1 MHz, etc.

In some embodiments, the pulser stage 1010, for example, may include any device capable of producing pulses greater than 500 V, peak current greater than 10 Amps, or pulse widths of less than about 10,000 ns, 1,000 ns, 100 ns, 10 ns, etc. As another example, the pulser stage 1010 may produce pulses with an amplitude greater than 1 kV, 5 kV, 10 kV, 50 kV, 200 kV, etc. As another example, the pulser stage 1010 may produce pulses with rise times or fall times less than about 5 ns, 50 ns, or 300 ns, etc.

In some embodiments, the pulser stage 1010 can produce a plurality of high voltage bursts. Each burst, for example, can include a plurality of high voltage pulses with fast rise times and fast fall times. The plurality of high voltage bursts, for example, can have a burst repetition frequency of about 10 Hz to 10 kHz. More specifically, for example, the plurality of high voltage bursts can have a burst repetition frequency of about 10 Hz, 100 Hz, 250 Hz, 500 Hz, 1 kHz, 2.5 kHz, 5.0 kHz, 10 kHz, etc.

Within each of the plurality of high voltage bursts, the high voltage pulses can have a pulse repetition frequency of about 1 kHz, 10 kHz, 100 kHz, 200 kHz, 500 kHz, 1 MHz, etc.

In some embodiments, the burst repetition frequency time from one burst till the next burst. Frequency at which the bias compensation switch is operated.

In some embodiments, the pulser stage 1010 can include one or more solid state switches 1025 (e.g., solid state switches such as, for example, IGBTs, a MOSFETs, a SiC MOSFETs, SiC junction transistors, FETs, SiC switches, GaN switches, photoconductive switches, etc.) coupled with a voltage source 1020. In some embodiments, the pulser stage 1010 can include one or more source snubber resistors 1030, one or more source snubber diodes 1037, one or more source snubber capacitors 1035, or one or more source freewheeling diodes 1040. One or more switches and or circuits can be arranged in parallel or series.

In some embodiments, the pulser stage 1010 can produce a plurality of high voltage pulses with a high frequency, fast rise times, fast fall times, at high frequencies, etc. The pulser stage 1010 may include one or more nanosecond pulsers.

In some embodiments, the pulser stage 1010 may comprise a high voltage pulsing power supply.

The pulser stage 1010 may, for example, include any pulser described in U.S. patent application Ser. No. 14/542,487, titled “High Voltage Nanosecond Pulser,” which is incorporated into this disclosure in its entirety for all purposes. The pulser stage 1010 may, for example, include any pulser described in U.S. Pat. No. 9,601,283, titled “Efficient IGBT Switching,” which is incorporated into this disclosure in its entirety for all purposes. The pulser stage 1010 may, for example, include any pulser described in U.S. patent application Ser. No. 15/365,094, titled “High Voltage Transformer,” which is incorporated into this disclosure in its entirety for all purposes.

The pulser stage 1010 may, for example, include a high voltage switch. As another example, the pulser stage 1010 may, for example, include any switch described in U.S. patent application Ser. No. 16/178,565, filed Nov. 1, 2018, titled “High Voltage Switch with Isolated Power,” which is incorporated into this disclosure in its entirety for all purposes.

In some embodiments, the pulser stage 1010 can include a transformer 814. The transformer 814 may include a transformer core (e.g., a toroid or non-toroid core); at least one primary winding wound once or less than once around the transformer core; and a secondary winding wound around the transformer core a plurality of times.

In some embodiments, the transformer 814 may include a single-turn primary winding and a multi-turn secondary windings around a transformer core. The single-turn primary winding, for example, may include one or more wires wound one or fewer times around a transformer core. The single-turn primary winding, for example, may include more than 2, 10, 20, 50, 100, 250, 1200, etc. individual single-turn primary windings. In some embodiments, the primary winding may include a conductive sheet.

The multi-turn secondary winding, for example, may include a single wire wound a plurality of times around the transformer core. The multi-turn secondary winding, for example, may be wound around the transformer core more than 2, 10, 25, 50, 100, 250, 500, etc. times. In some embodiments, a plurality of multi-turn secondary windings may be wound around the transformer core. In some embodiments, the secondary winding may include a conductive sheet.

In some embodiments, the high-voltage transformer may be used to output a voltage greater than 1,000 volts with a fast rise time of less than 150 nanoseconds or less than 50 nanoseconds, or less than 5 ns.

In some embodiments, the high-voltage transformer may have a low impedance and/or a low capacitance. For example, the high-voltage transformer has a stray inductance of less than 100 nH, 50 nH, 30 nH, 20 nH, 10 nH, 2 nH, 100 pH as measured on the primary side and/or the transformer has a stray capacitance of less than 100 pF, 30 pF, 10 pF, 1 pF as measured on the secondary side.

The transformer 814 may comprise a transformer as disclosed in U.S. patent application Ser. No. 15/365,094, titled “High Voltage Transformer,” which is incorporated into this document for all purposes.

FIG. 11 is a circuit diagram of a nanosecond pulser 1100 driving a plasma within the plasma chamber 725 according to some embodiments. In this example, the nanosecond pulser 1000 is one example of a nanosecond pulser 115. The nanosecond pulser 1100 may be coupled with the RF driver 105 and the filter 140. In this example, the nanosecond pulser 1100 may include pulser stage 1010, an energy recovery circuit 905, and/or a bias compensation circuit 825. Various other circuit elements may be included. Various other circuit elements may be included.

The nanosecond pulser 1100 is similar to the nanosecond pulser 1000 but without the resistive output stage 820 and includes an energy recovery circuit 905. In some embodiments, the energy recovery circuit 905 and/or the bias compensation circuit 825 may be optional.

In this example, the energy recovery circuit 905 may be positioned on or electrically coupled with the secondary side of the transformer 814. The energy recovery circuit 905, for example, may include a diode 930 (e.g., a crowbar diode) across the secondary side of the transformer 814. The energy recovery circuit 905, for example, may include diode 915 and inductor 910 (arranged in series), which can allow current to flow from the secondary side of the transformer 814 to charge the power supply 806 and current to flow to the plasma chamber 725. The diode 915 and the inductor 910 may be electrically connected with the secondary side of the transformer 814 and coupled with the power supply 806. The diode 915 and the inductor 910 may be arranged in any order. In some embodiments, the energy recovery circuit 905 may include diode 920 and/or inductor 925 electrically coupled with the secondary of the transformer 814. The inductor 910 may represent the stray inductance and/or may include the stray inductance of the transformer 814.

When the RF source 805 is turned on, current may charge the plasma chamber 725 (e.g., charge the capacitor 735, capacitor 730, or capacitor 740). Some current, for example, may flow through inductor 910 when the voltage on the secondary side of the transformer 814 rises above the charge voltage on the power supply 806. When the nanosecond pulser is turned off, current may flow from the capacitors within the plasma chamber 725 through the inductor 910 to charge the power supply 806 until the voltage across the inductor 910 is zero. The diode 930 may prevent the capacitance within the plasma chamber 725 from ringing with the inductance in the plasma chamber 725 or the bias compensation circuit 825.

The diode 915 may, for example, prevent charge from flowing from the power supply 806 to the capacitors within the plasma chamber 725.

The inductance value of inductor 910 can be selected to control the current fall time. In some embodiments, the inductor 910 can have an inductance value between 1 μH-500 μH.

In some embodiments, the energy recovery circuit 905 may include a switch that can be used to control the flow of current through the inductor 910. The switch, for example, may be placed in series with the inductor 910.

A switch in the energy recovery circuit 905, for example, may include a high voltage switch such as, for example, the high voltage switch disclosed in U.S. patent application Ser. No. 16/178,565 filed Nov. 1, 2018, titled “HIGH VOLTAGE SWITCH WITH ISOLATED POWER,” which claims priority to U.S. Provisional Patent Application No. 62/717,637 filed Aug. 10, 2018, both of which are incorporated by reference in the entirety.

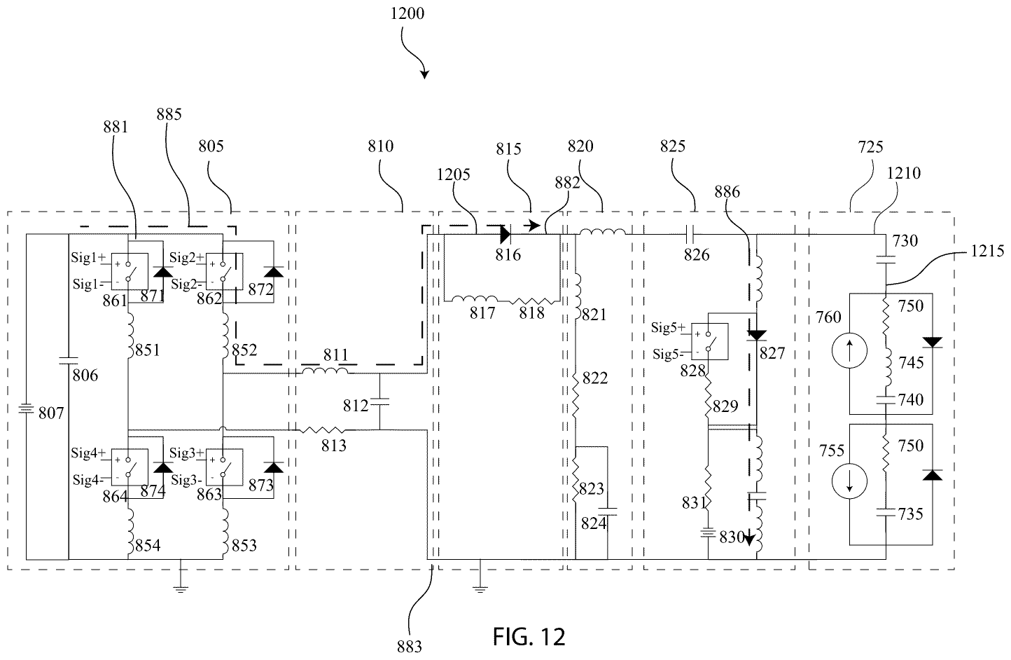

FIG. 12 is a circuit diagram of an RF driver circuit 1200 driving the plasma chamber 725 according to some embodiments. The RF driver circuit 1200 is similar to RF driver 800. While the transformer 814 is removed, a transformer may be used.

The RF source 805 may drive the resonant circuit 810 at the resonant frequency of the resonant inductor 811, resonant capacitor 812, and/or resonant resistor 813.

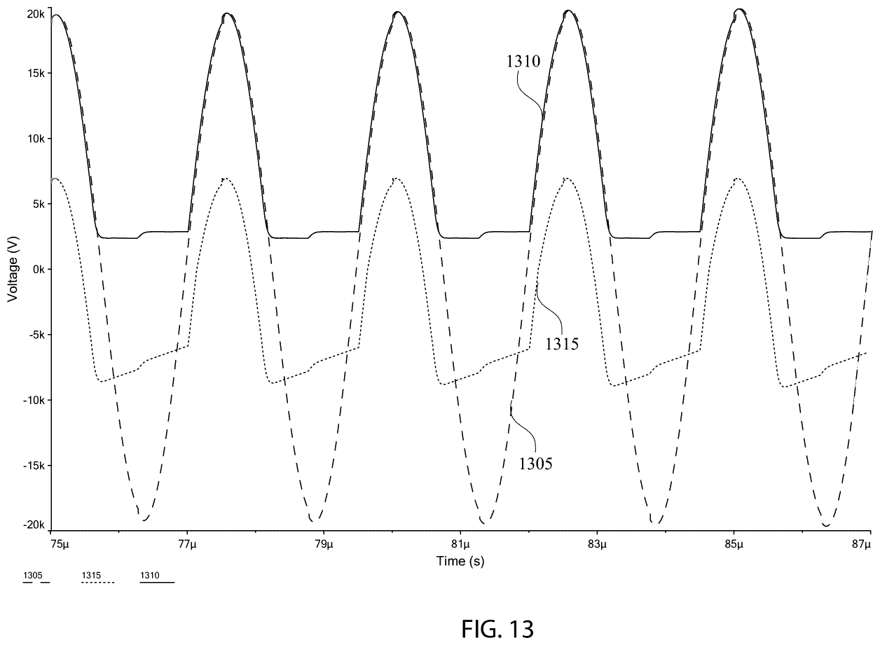

The rectifying diode 816 (without droop control inductor 817 and droop control resistor 818) may rectify the sinusoidal waveform produced by the RF source 805 and the resonant circuit 810 as shown in waveform 1310 of FIG. 13, which shows the voltage measured over time at point 1210. The result on the wafer is shown in waveform 1315, which shows the voltage measured over time at point 1215. The voltage produced by the RF source 805 and the resonant circuit 810 is shown in waveform 1305. The flat portion of waveform 1315 has some negative going droop. Droop is the non-flat portion of the waveform caused by the ion current in the plasma. In this example, the droop is an upward sloping of the portion of waveform 1315 shown from approximately 8 kV sloping up to 5 kV. In some embodiments, it may be beneficial to have this portion of the waveform 1310 remain at near constant voltage as this is directly correlated to ion energy falling to the wafer surface.

The proper selection of the droop control inductor 817 and the droop control resistor 818 based on the RF frequency, RF voltage and ion current to the wafer can compensate for the droop in waveform 1315. The droop control inductor 817 and the droop control resistor 818 may allow for some portion of the negative portion of the resonant sinewave to flow to point 1210, which replaces the loss charge on capacitor 730 due to ion current flowing to point 1215. The droop control inductor 817 or the droop control resistor 818 may be replaced by a droop control capacitor or a droop control capacitor may be added. The droop control resistor 818 may include or comprise stray resistance throughout the circuit. The values of the droop control inductor 817 and the droop control resistor 818 may be selected based on the resonant frequency, output resonant voltage amplitude (e.g., of waveform 1305), and/or the amplitude of the ion current on the wafer surface of the resonant circuit 810.

In some embodiments, the droop control inductor 817, the droop control resistor 818, and/or the droop control capacitor may be predetermined or controlled in real time. For example, the droop control inductor 817 may include a variable inductor, the droop control resistor 818 may include a variable resistor, and/or the droop control capacitor may comprise a variable capacitor.

In some embodiments, the impedance of either the droop control resistor 818 and/or the drop control inductor 817 at a given frequency and voltage may be equal to or less than required to balance the discharge rate of capacitor 730.

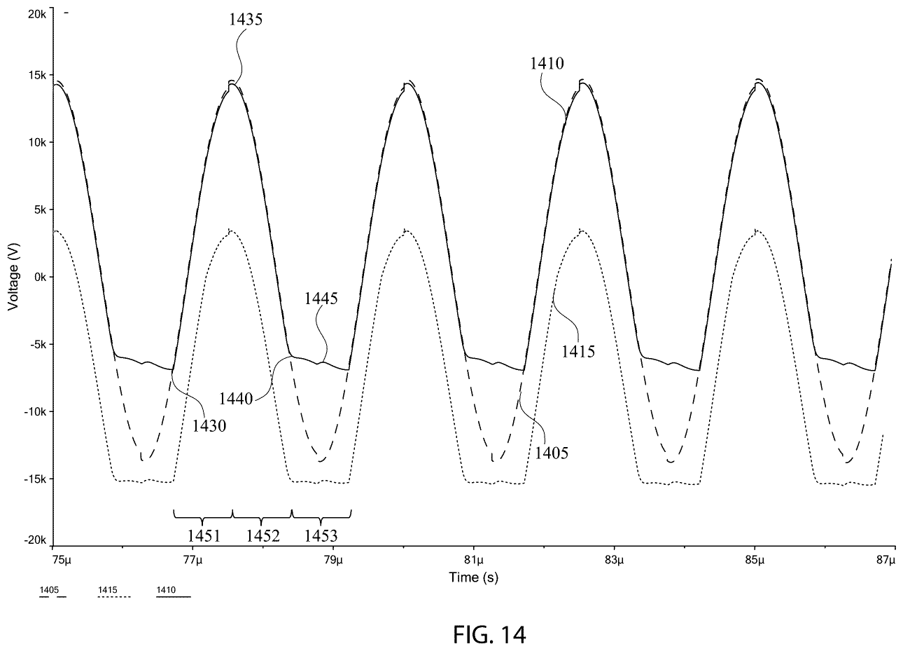

As shown in waveform 1415 of FIG. 14, the droop on the wafer can be removed with the inclusion of the droop control inductor 817 and the droop control resistor 818. The droop control inductor 817 and the droop control resistor 818 may allow current to flow back through the circuit causing a negative going rectification as shown in the portions of waveform 1410 that should be flat but are otherwise slopping downward. In some embodiments, it may be beneficial to have this portion of the waveform 1410 remain at near constant voltage as this is directly correlated to ion energy falling to the wafer surface.

As shown in FIG. 14, the waveform 1410 applied at the output node 882 begins to move (over a first portion 1451 of the of the periodic voltage waveform) from a first negative voltage 1430 to a positive peak voltage 1435. The current through the first current pathway 885 drops to zero and the asymmetric periodic voltage drops from the positive peak voltage 1435. Then, during a second portion 1452 of the asymmetrical waveform, unidirectional current begins to flow through the second current pathway 882 through the diode, 827. The rise and fall of the unidirectional current occurs while the asymmetrical periodic voltage changes (during the second portion 1452) from the positive peak voltage 1435 to a third, negative, voltage level 1440. The first portion 1451 of the asymmetric periodic voltage causes the sheath voltage to approach a positive voltage to repel positive charges (that accumulate on the surface of the workpiece while the surface of the workpiece is held at a negative voltage), and the second portion 1452 of the asymmetric periodic voltage causes the sheath voltage to become a desired negative voltage (or range of voltages) to achieve an ion flux that achieves a desired ion energy.

After the unidirectional current rises and falls back to a level of zero current, the asymmetrical periodic voltage, waveform 1410, becomes more negative (as a negative voltage ramp) during a fourth portion 1453. During the fourth portion 1453, the waveform 1410 ramps negative with a downward sloping droop.

In some embodiments, the droop control inductor 817 may have an inductance less than about 100 mH, 50 mH, 10 mH., 5 mH, etc. In some embodiments, the drop control inductor 817 may have an inductance less than about 0.1 mH, 0.5 mH, 1 mH, 5 mH, 10 mH, etc.

In some embodiments, the droop control resistor 818 may comprise a resistor or stray resistance that is less than about 10 mΩ, 50 mΩ, 100 mΩ, 250 mΩ, 500 mΩ, etc. In some embodiments, the droop control resistor 818 may comprise a resistor or stray resistance that is less than about 10Ω, 50Ω, 100Ω, 250Ω, 500Ω, etc.

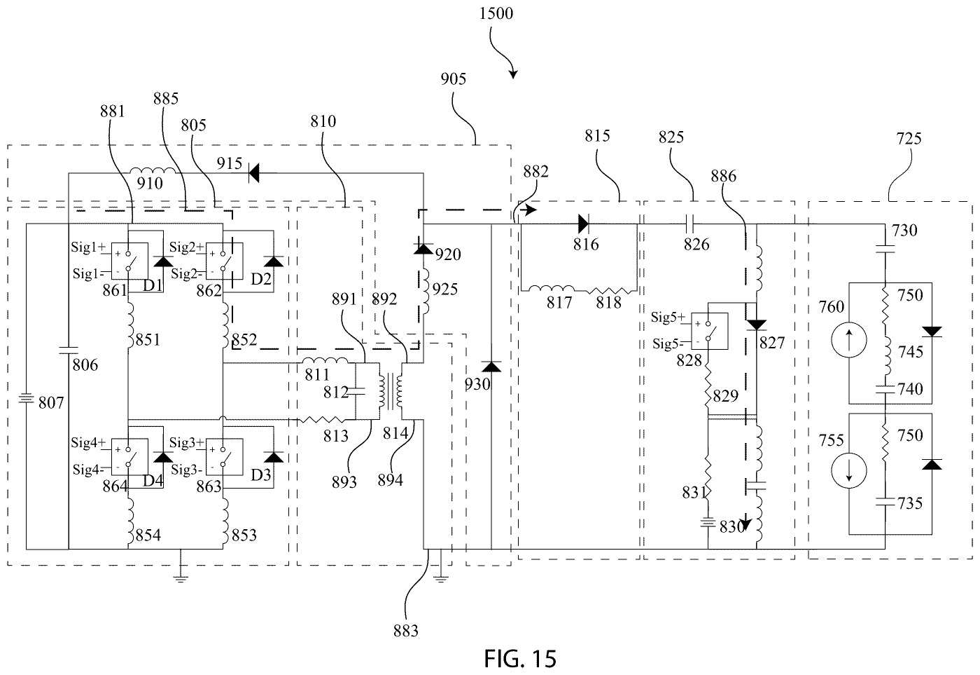

FIG. 15 is a circuit diagram of an RF driver circuit 1500 driving the plasma chamber 725 according to some embodiments. The RF driver circuit 1500 is similar to RF driver circuit 1200 with the resistive output stage 820 is replaced with an energy recovery circuit 905. The resistive output stage 820 and the energy recovery circuit 905 can be referred to as energy sink circuits. The droop control inductor 817 and droop control resistor 818 may correct for any droop in the circuit.

In some embodiments, such as, for example, as shown in FIG. 8, an RF driver may include a first node 881, a second node 882, and a third node 883.

The resonant switch section comprises a first node 881, a second node 882, a third node 883 (e.g., ground), and a first current pathway 885 between the first node 881 and the second node 882, which comprises a series combination of a switch (e.g., switch S2) and a diode (e.g., diode D13 or D7). The resonant switch section also comprises a second current pathway 886 between the second node 882 and the third node 883 that comprises a diode (e.g., D8) and an inductive element (e.g., L23). When the switch(es) is closed, unidirectional current in the first and second current pathways causes an application of the periodic voltage between the output 620 and ground (the return node).

In some examples, a power section that includes a first voltage source (e.g., V1) can be coupled between the third node 883 and the first node 881. In some examples, a second voltage source (e.g., V5) may be coupled to the return node (ground).

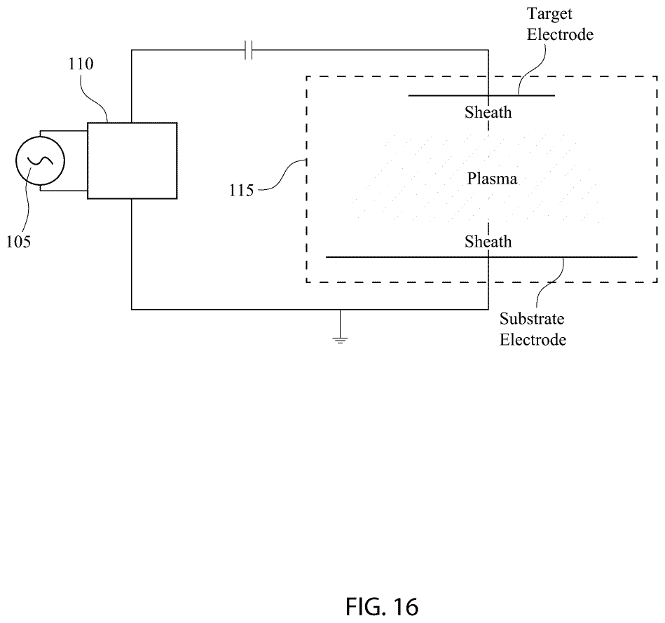

In some embodiments, systems and methods are disclosed to provide switching power to a plasma chamber without the use of a matching network. As shown in FIG. 16, a typical RF driver 105 requires a matching network 110, for example, to ensure the impedance of the RF driver 105 matches the impedance of the plasma chamber 115. To accomplish this, a matching network 110 can include any combinations of transformers, resistors, inductors, capacitors, and/or transmission lines. Often the matching network 110 may need to be tuned to ensure that the impedance of the RF driver 105 and the impedance of the plasma chamber 115 match. This tuning may be required during plasma processing. Matching networks, however, can be relatively slow at tuning (e.g., requiring at best lest than around tens or hundreds of milliseconds to tune), which may not allow real time tuning.

Embodiments described in this disclosure include circuits and processes for driving switching power to a plasma chamber without a matching network. In some embodiments, a full (or half) bridge circuit may be used to drive a resonant circuit at its resonant frequency. Because the resonant circuit is being driven at its resonant frequency, the output voltage of the resonant circuit may be higher than the input voltage. In some embodiments, this resonant condition may allow for a drive voltage of a few hundred volts to generate about 4 kV or more of output voltage at a transformer.

As used throughout this disclosure, the term “high voltage” may include a voltage greater than 500 V, 1 kV, 10 kV, 20 kV, 50 kV, 100 kV, etc.; the term “high frequency” may be a frequency greater than 100 Hz, 250 Hz, 500 Hz, 750 Hz, 1 kHz, 10 kHz, 100 kHz, 200 kHz, 500 kHz, 1 MHz, 10 MHz, 50 MHz, 100 MHz, etc., the term “fast rise time” may include a rise time less than about 1 ns, 10 ns, 50 ns, 100 ns, 250 ns, 500 ns, 1,000 ns, etc.; the term “fast fall time” may include a fall time less than about 1 ns, 10 ns, 50 ns, 100 ns, 250 ns, 500 ns, 1,000 ns, etc.); and the term short pulse width may include pulse widths less than about 1 ns, 10 ns, 50 ns, 100 ns, 250 ns, 500 ns, 1,000 ns, etc.).

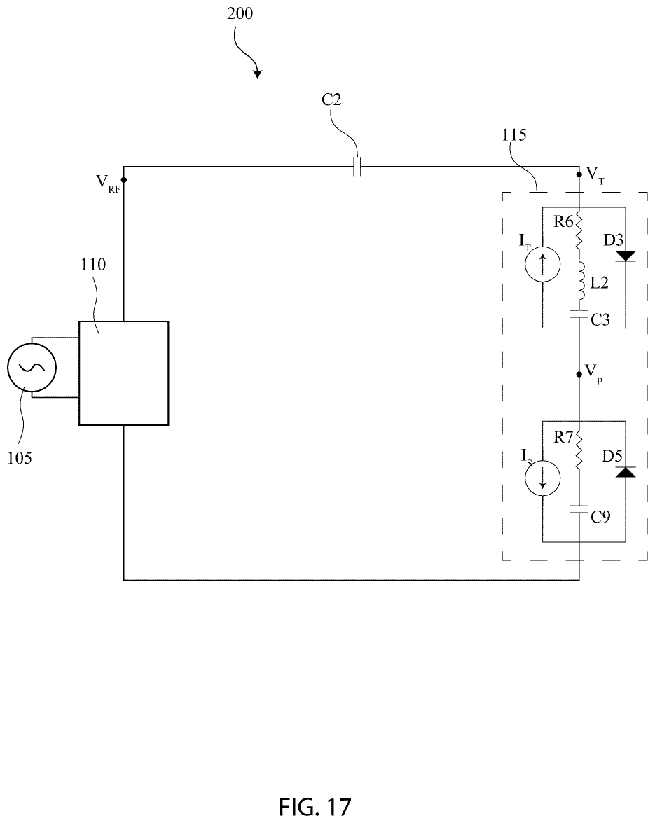

FIG. 17 is schematic of an equivalent electric circuit model 200 for an RF driver 105, which may be an RF power supply, and an equivalent circuit of a plasma chamber 115. In this example, V_{RF} is the voltage of the applied RF signal from a RF driver 105 with a matching network 110. V_{T} and V_{P} are the potentials of the target electrode and the plasma, respectively. In addition, V_{SS}=V_{P} and V_{ST}=V_{T}−V_{P} are the voltages across the substrate or chamber wall plasma sheath (V_{SS}) and the target plasma sheath (V_{ST}), respectively. The blocking capacitor is represented by C2; C3 and I_{T} represent the capacitance and the conduction current through the sheath adjacent to the target electrode, respectively, while C9 and I_{S} represent the corresponding values of the capacitance and current for the sheath adjacent to the substrate electrode.

In some embodiments, the electrical resistance of the plasma may be small with respect to the sheath resistance for the plasma electron densities and voltage frequencies described in this disclosure. However, inclusion of the plasma resistance does not introduce any complications for the circuit model.

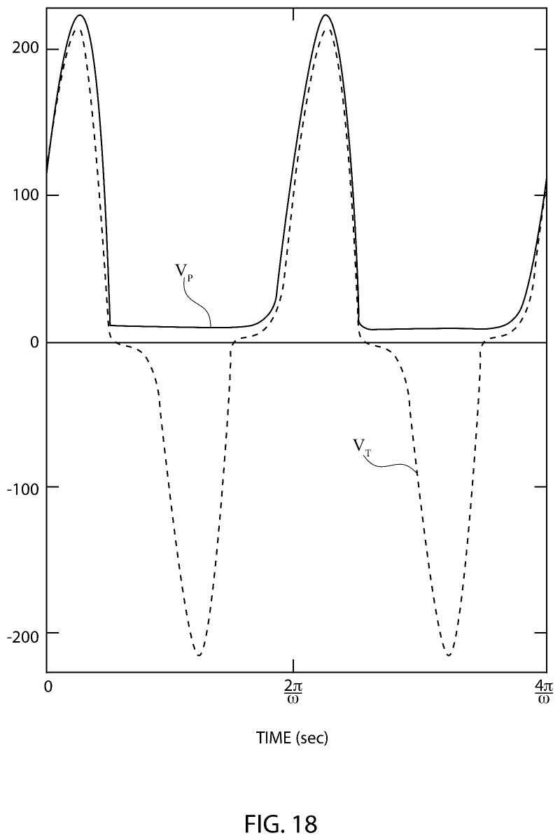

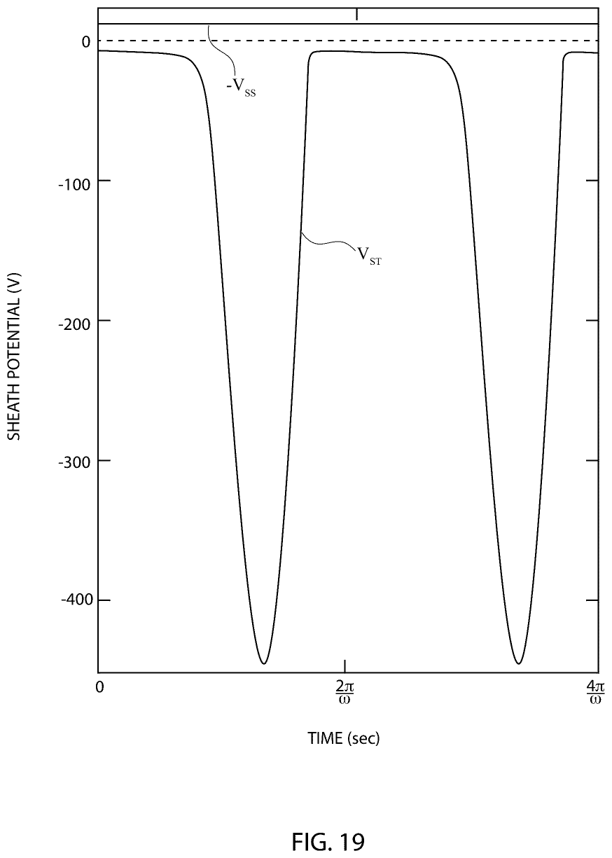

FIG. 18. Illustrates waveforms of the voltage V_{T} across a plasma reactor such as, for example, those shown in FIG. 16 and FIG. 17, and the plasma potential V_{P} for equal areas of the target and substrate electrodes. FIG. 19 Illustrates calculated waveforms of the potential V_{ST} across the plasma sheath adjacent to the target electrode shown in FIG. 16 and that of the potential V_{SS} across the sub-strate electrode sheath for A_{T}/A_{S}=0.2, where A_{T} and A_{S} are the areas of the target electrode and the substrate electrode respectively. FIG. 19 shows the half sine wave of the sheath potential going from 0 to −450V.

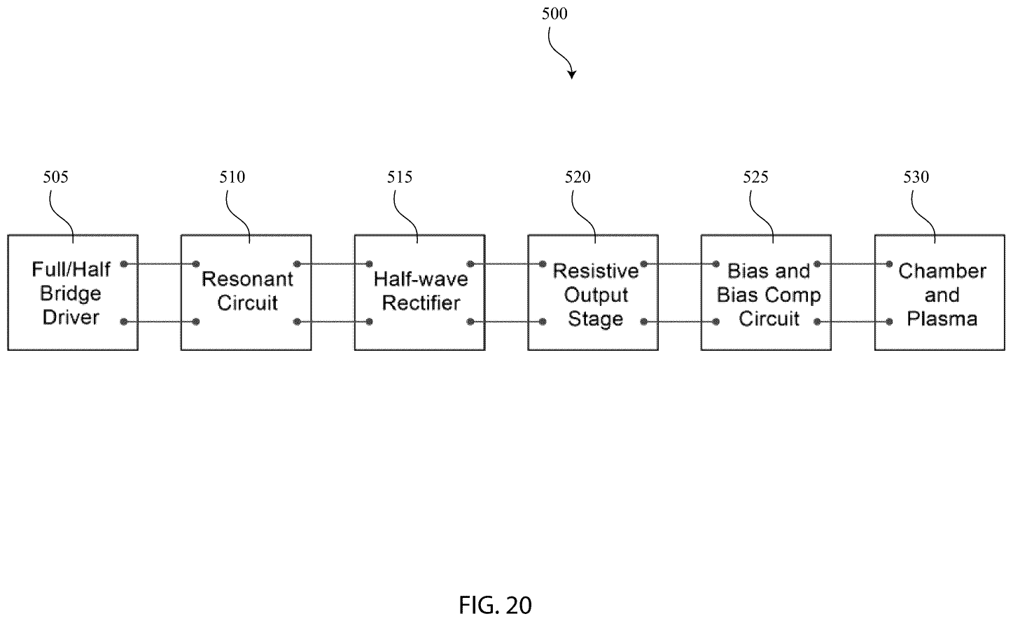

FIG. 20 is a block diagram of a driver and chamber circuit 500 without a matching network according to some embodiments. The driver and chamber circuit 500 may include an RF driver 505 that may include a voltage source and either a full-bridge driver or a half bridge driver or an equivalent driver. The driver and chamber circuit 500 may include a resonant circuit 510 having a transformer and resonant elements. The driver and chamber circuit 500 may include may also include a half-wave rectifier 515 electrically coupled with the resonant circuit 510. A resistive output stage 520 (or an energy recovery circuit) may be coupled with the half-wave rectifier. A bias compensation circuit 525 may be coupled with the resistive output stage 520. The plasma and chamber 530 and a plasma may be coupled with the bias compensation circuit 525.

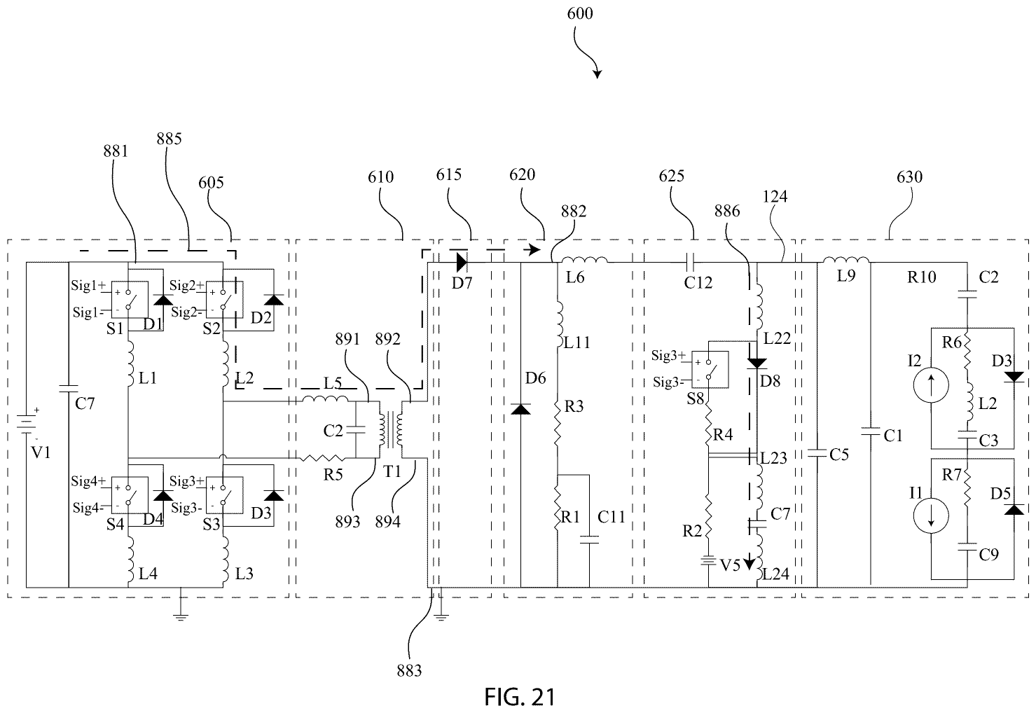

FIG. 21 is a circuit diagram of a driver and chamber circuit 600 according to some embodiments.

In this example, the driver and chamber circuit 600 may include an RF driver 605. The RF driver 605, for example, may be a half-bridge driver or a full-bridge driver as shown in FIG. 21. The RF driver 605 may include an input voltage source V1 that may be a DC voltage source (e.g., a capacitive source, AC-DC converter, etc.). In some embodiments, the RF driver 605 may include four switches S1, S2, S3, and S4. In some embodiments, the RF driver 605 may include a plurality of switches S1, S2, S3, and S4 in series or in parallel. These switches S1, S2, S3, and S4, for example, may include any type of solid-state switch such as, for example, IGBTs, a MOSFETs, a SiC MOSFETs, SiC junction transistors, FETs, SiC switches, GaN switches, photoconductive switches, etc. These switches S1, S2, S3, and S4 may be switched at high frequencies and/or may produce a high voltage pulses. These frequencies may, for example, include frequencies of about 400 kHz, 0.5 MHz, 2.0 MHz, 4.0 MHz, 13.56 MHz, 27.12 MHz, 40.68 MHz, 50 MHz, etc.

Each switch of switches S1, S2, S3, and S4 may be coupled in parallel with a respective diode D1, D2, D3, and D4 and may include stray inductance represented by inductor L1, L2, L3, and LA. In some embodiments, the inductances of inductor L1, L2, L3, and L4 may be equal. In some embodiments, the inductances of inductor L1, L2, L3, and L4 may be less than about 50 nH, 100 nH, 150 nH, 500 nH, 1,000 nH, etc. The combination of a switch (S1, S2, S3, or S4) and a respective diode (D1, D2, D3, or D4) may be coupled in series with a respective inductor (L1, L2, L3, or L4). Inductors L3 and LA are connected with ground. Inductor L1 is connected with switch S4 and the resonant circuit 610. And inductor L2 is connected with switch S3 and the opposite side of the resonant circuit 610.

In some embodiments, the RF driver 605 may be coupled with a resonant circuit 610. The resonant circuit 610 may include a resonant inductor L5 and/or a resonant capacitor C2 coupled with a transformer T1. The resonant circuit 610 may include a resonant resistance R5, for example, that may include the stray resistance of any leads between the RF driver 605 and the resonant circuit 610 and/or any component within the resonant circuit 610 such as, for example, the transformer T1, the capacitor C2, and/or the inductor L5. In some embodiments, the resonant resistance R5 comprises only stray resistances of wires, traces, or circuit elements. While the inductance and/or capacitance of other circuit elements may affect the driving frequency, the driving frequency can be set largely by choice of the resonant inductor L5 and/or the resonant capacitor C2. Further refinements and/or tuning may be required to create the proper driving frequency in light of stray inductance or stray capacitance. In addition, the rise time across the transformer T1 can be adjusted by changing L5 and/or C2, provided that:

$${f}_{resonant} = \frac{1}{2 π \sqrt{( L 5 ) ( C 2 )}} = constant .$$

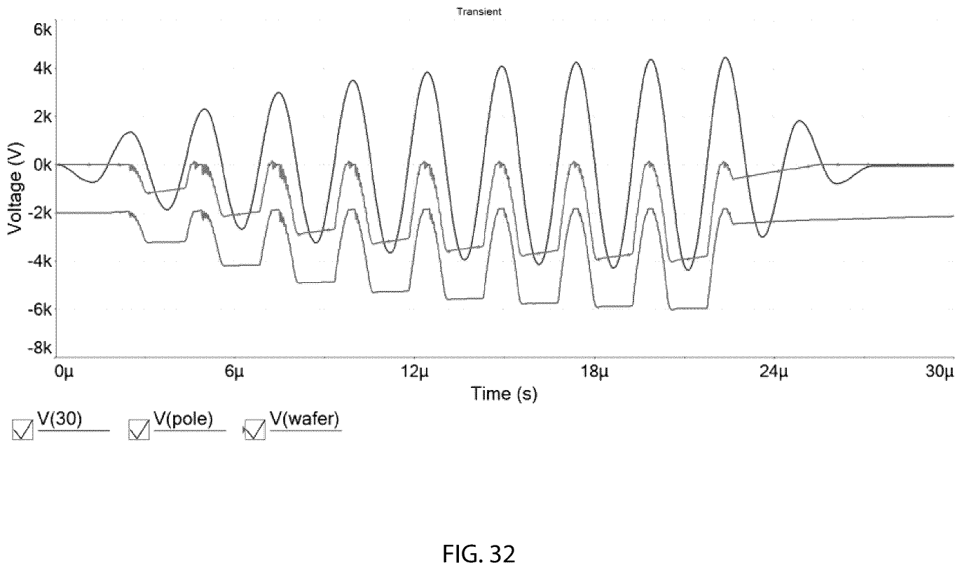

In some embodiments, large inductance values for L5 can result in slower or shorter rise times. These values may also affect the burst envelope. As shown in FIG. 32, each burst can include transient and steady state pulses. The transient pulses within each burst may be set by L5 and/or the Q of the system until full voltage is reached during the steady state pulses.

If the switches in the RF driver 605 are switched at the resonant frequency, fᵣₑₛₒₙₐₙₜ, then the output voltage at the transformer T1 will be amplified. In some embodiments, the resonant frequency may be about 400 kHz, 0.5 MHz, 2.0 MHz, 4.0 MHz, 13.56 MHZ, 27.12 MHz, 40.68 MHz, 50 MHz, etc.

In some embodiments, the resonant capacitor C2 may include the stray capacitance of the transformer T1 and/or a physical capacitor. In some embodiments, the resonant capacitor C2 may have a capacitance of about 10 μF, 1 μF, 100 nF, 10 nF, etc. In some embodiments, the resonant inductor L5 may include the stray inductance of the transformer T1 and/or a physical inductor. In some embodiments, the resonant inductor L5 may have an inductance of about 50 nH, 100 nH, 150 nH, 500 nH, 1,000 nH, etc. In some embodiments, the resonant resistor R5 may have a resistance of about 10 ohms, 25 ohms, 50 ohms, 100 ohms, 150 ohms, 500 ohms, etc.

In some embodiments, the resonant resistor R5 may represent the stray resistance of wires, traces, and/or the transformer windings within the physical circuit. In some embodiments, the resonant resistor R5 may have a resistance of about 10 mohms, 50 mohms, 100 mohms, 200 mohms, 500 mohms, etc.

In some embodiments, the transformer T1 may comprise a transformer as disclosed in U.S. patent application Ser. No. 15/365,094, titled “High Voltage Transformer,” which is incorporated into this document for all purposes. In some embodiments, the output voltage of the resonant circuit 610 can be changed by changing the duty cycle (e.g., the switch “on” time or the time a switch is conducting) of switches S1, S2, S3, and/or S4. For example, the longer the duty cycle, the higher the output voltage; and the shorter the duty cycle, the lower the output voltage. In some embodiments, the output voltage of the resonant circuit 610 can be changed or tuned by adjusting the duty cycle of the switching in the RF driver 605.

For example, the duty cycle of the switches can be adjusted by changing the duty cycle of signal Sig1, which opens and closes switch S1; changing the duty cycle of signal Sig2, which opens and closes switch S2; changing the duty cycle of signal Sig3, which opens and closes switch S3; and changing the duty cycle of signal Sig4, which opens and closes switch S4. By adjusting the duty cycle of the switches S1, S2, S3, or S4, for example, the output voltage of the resonant circuit 610 can be controlled.

In some embodiments, each switch S1, S2, S3, or S4 in the resonant circuit 605 can be switched independently or in conjunction with one or more of the other switches. For example, the signal Sig1 may be the same signal as signal Sig3. As another example, the signal Sig2 may be the same signal as signal Sig4. As another example, each signal may be independent and may control each switch S1, S2, S3, or S4 independently or separately.

In some embodiments, the resonant circuit 610 may be coupled with a half-wave rectifier 615 that may include a blocking diode D7.

In some embodiments, the half-wave rectifier 615 may be coupled with the resistive output stage 620. The resistive output stage 620 may include any resistive output stage known in the art. For example, the resistive output stage 620 may include any resistive output stage described in U.S. patent application Ser. No. 16/178,538 titled “HIGH VOLTAGE RESISTIVE OUTPUT STAGE CIRCUIT,” which is incorporated into this disclosure in its entirety for all purposes.

For example, the resistive output stage 620 may include an inductor L11, resistor R3, resistor R1, and capacitor C11. In some embodiments, inductor L11 may include an inductance of about 5 μH to about 25 μH. In some embodiments, the resistor R1 may include a resistance of about 50 ohms to about 250 ohms. In some embodiments, the resistor R3 may comprise the stray resistance in the resistive output stage 620.

In some embodiments, the resistor R1 may include a plurality of resistors arranged in series and/or parallel. The capacitor C11 may represent the stray capacitance of the resistor R1 including the capacitance of the arrangement series and/or parallel resistors. The capacitance of stray capacitance C11, for example, may be less than 500 pF, 250 pF, 100 pF, 50 pF, 10 pF, 1 pF, etc. The capacitance of stray capacitance C11, for example, may be less than the load capacitance such as, for example, less than the capacitance of C2, C3, and/or C9.

In some embodiments, the resistor R1 may discharge the load (e.g., a plasma sheath capacitance). In some embodiments, the resistive output stage 620 may be configured to discharge over about 1 kilowatt of average power during each pulse cycle and/or a joule or less of energy in each pulse cycle. In some embodiments, the resistance of the resistor R1 in the resistive output stage 620 may be less than 200 ohms. In some embodiments, the resistor R1 may comprise a plurality of resistors arranged in series or parallel having a combined capacitance less than about 200 pF (e.g., C11).

In some embodiments, the resistive output stage 620 may include a collection of circuit elements that can be used to control the shape of a voltage waveform on a load. In some embodiments, the resistive output stage 620 may include passive elements only (e.g., resistors, capacitors, inductors, etc.). In some embodiments, the resistive output stage 620 may include active circuit elements (e.g., switches) as well as passive circuit elements. In some embodiments, the resistive output stage 620, for example, can be used to control the voltage rise time of a waveform and/or the voltage fall time of waveform.

In some embodiments, the resistive output stage 620 can discharge capacitive loads (e.g., a wafer and/or a plasma). For example, these capacitive loads may have small capacitance (e.g., about 10 pF, 100 pF, 500 pF, 1 nF, 10 nF, 100 nF, etc.).

In some embodiments, a resistive output stage can be used in circuits with pulses having a high pulse voltage (e.g., voltages greater than 1 kV, 10 kV, 20 kV, 50 kV, 100 kV, etc.) and/or high frequencies (e.g., frequencies greater than 1 kHz, 10 kHz, 100 kHz, 200 kHz, 500 kHz, 1 MHz, etc.) and/or frequencies of about 400 kHz, 0.5 MHz, 2.0 MHz, 4.0 MHz, 13.56 MHz, 27.12 MHz, 40.68 MHz, 50 MHz, etc.

In some embodiments, the resistive output stage may be selected to handle high average power, high peak power, fast rise times and/or fast fall times. For example, the average power rating might be greater than about 0.5 kW, 1.0 kW, 10 KW, 25 KW, etc., and/or the peak power rating might be greater than about 1 kW, 10 KW, 100 KW, 1 MW, etc.

In some embodiments, the resistive output stage 620 may include a series or parallel network of passive components. For example, the resistive output stage 620 may include a series of a resistor, a capacitor, and an inductor. As another example, the resistive output stage 620 may include a capacitor in parallel with an inductor and the capacitor-inductor combination in series with a resistor. For example, L11 can be chosen large enough so that there is no significant energy injected into the resistive output stage when there is voltage out of the rectifier. The values of R3 and R1 can be chosen so that the L/R time can drain the appropriate capacitors in the load faster than the RF frequency

In some embodiments, the resistive output stage 620 may be coupled with the bias compensation circuit 625. The bias compensation circuit 625 may include any bias and/or bias compensation circuit known in the art. For example, the bias compensation circuit 625 may include any bias and/or bias compensation circuit described in U.S. patent application Ser. No. 16/523,840 titled “NANOSECOND PULSER BIAS COMPENSATION,” which is incorporated into this disclosure in its entirety for all purposes.

In some embodiments, the bias compensation circuit 625 may include a bias capacitor C7, blocking capacitor C12, a blocking diode D8, switch S8 (e.g., a high voltage switch), offset supply voltage V1, resistance R2, and/or resistance R4. In some embodiments, the switch S8 comprises a high voltage switch described in U.S. Patent Application No. 62/717,637, titled “HIGH VOLTAGE SWITCH FOR NANOSECOND PULSING,” and/or in U.S. patent application Ser. No. 16/178,565, titled “HIGH VOLTAGE SWITCH FOR NANOSECOND PULSING,” which is incorporated into this disclosure in its entirety for all purposes.

In some embodiments, the offset supply voltage V5 may include a DC voltage source that can bias the output voltage either positively or negatively. In some embodiments, the capacitor C12 may isolate/separate the offset supply voltage V5 from the resistive output stage 620 and/or other circuit elements. In some embodiments, the bias compensation circuit 625 may allow for a potential shift of power from one portion of the circuit to another. In some embodiments, the bias compensation circuit 625 may be used to hold a wafer in place as high voltage pulses are active within the chamber. Resistance R2 may protect/isolate the DC bias supply from the driver.

In some embodiments, the switch S8 may be open while the RF driver 605 is pulsing and closed when the RF driver 605 is not pulsing. While closed, the switch S8 may, for example, short current across the blocking diode D8. Shorting this current may allow the bias between the wafer and the chuck to be less than 2 kV, which may be within acceptable tolerances.

In some embodiments, the plasma and chamber 630 may be coupled with the bias compensation circuit 625. The plasma and chamber 630, for example, may be represented by the various circuit elements shown in FIG. 21.

FIG. 21 does not include a traditional matching network such as, for example, a 50 ohm matching network or an external matching network or standalone matching network. Indeed, the embodiments described within this document do not require a 50 ohm matching network to tune the switching power applied to the wafer chamber. In addition, embodiments described within this document provide a variable output impedance RF generator without a traditional matching network. This can allow for rapid changes to the power drawn by the plasma chamber. Typically, this tuning of the matching network can take at least 100 μs-200 μs. In some embodiments, power changes can occur within one or two RF cycles, for example, 2.5 μs-5.0 μs at 400 kHz.

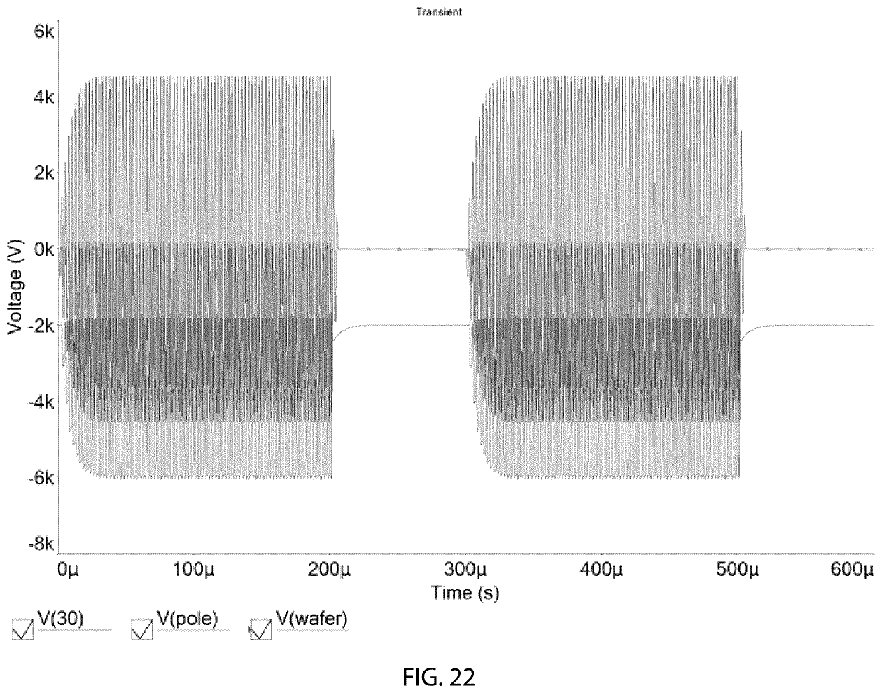

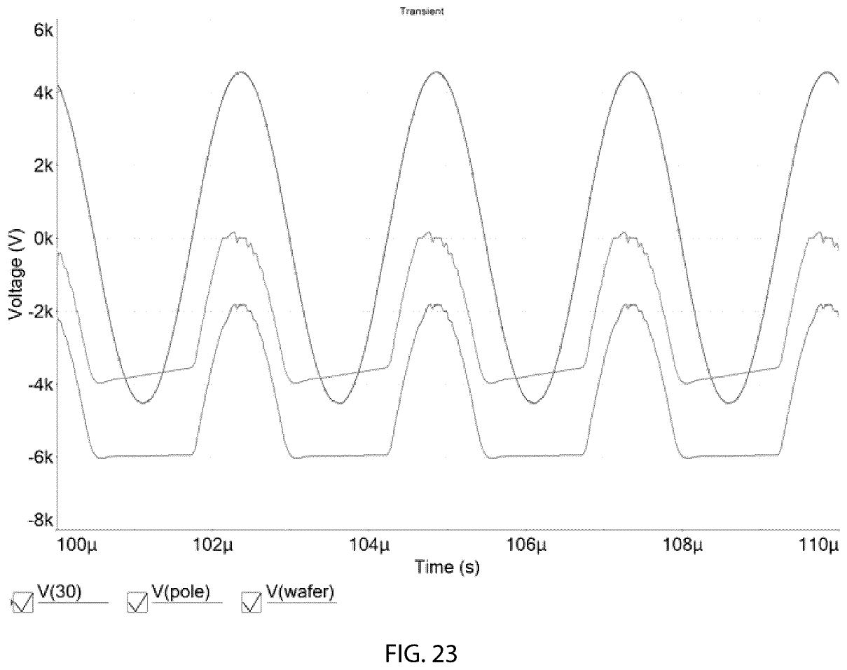

FIG. 22 is a waveform of the voltage across the transformer T1 (red), at the Pole (green), and at the wafer (blue) for a time frame of 600 μs. FIG. 23 is a zoomed view of the waveform over a time frame of 10 μs.

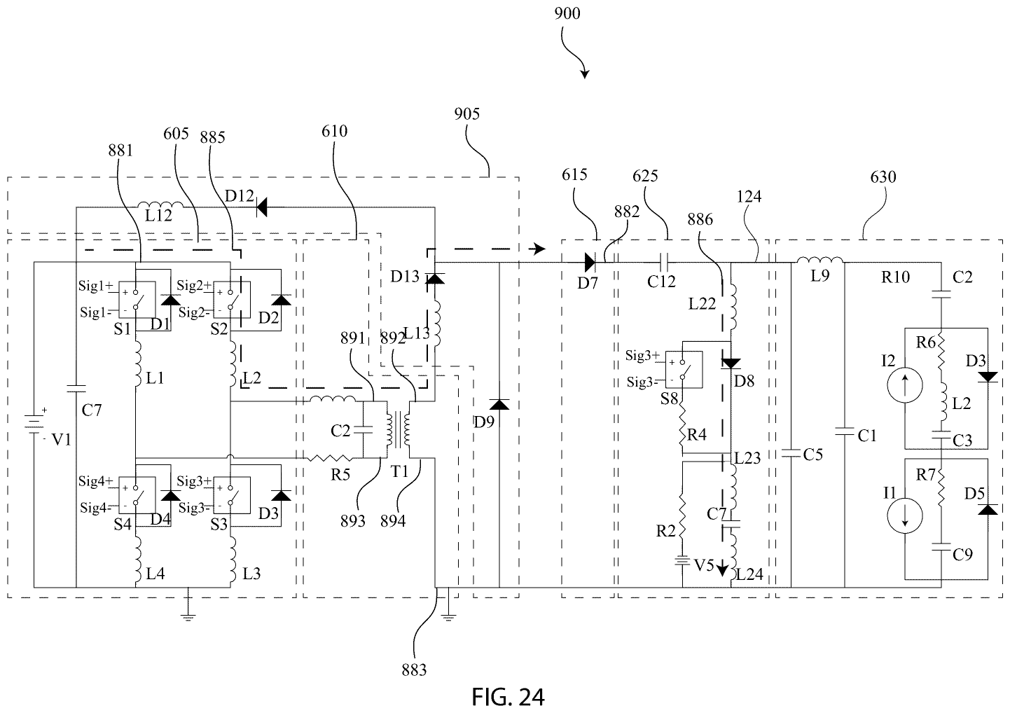

FIG. 24 is a circuit diagram of an RF Driver 900 according to some embodiments. The RF Driver 900, for example, may include the RF driver 605, the resonant circuit 610, the bias compensation circuit 625, and the plasma and chamber 630. The RF Driver 900 is similar to the driver and chamber circuit 600 but without the resistive output stage 620 and includes an energy recovery circuit 905.

In this example, the energy recovery circuit 905 may be positioned on or electrically coupled with the secondary side of the transformer T1. The energy recovery circuit 905, for example, may include a diode D9 (e.g., a crowbar diode) across the secondary side of the transformer T1. The energy recovery circuit 905, for example, may include diode D10 and inductor L12 (arranged in series), which can allow current to flow from the secondary side of the transformer T1 to charge the power supply C15 and current to flow to the plasma and chamber 630. The diode D12 and the inductor L12 may be electrically connected with the secondary side of the transformer T1 and coupled with the power supply C15. In some embodiments, the energy recovery circuit 905 may include diode D13 and/or inductor L13 electrically coupled with the secondary of the transformer T1. The inductor L12 may represent the stray inductance and/or may include the stray inductance of the transformer T1.

When the nanosecond pulser is turned on, current may charge the plasma and chamber 630 (e.g., charge the capacitor C3, capacitor C2, or capacitor C9). Some current, for example, may flow through inductor L12 when the voltage on the secondary side of the transformer T1 rises above the charge voltage on the power supply C15. When the nanosecond pulser is turned off, current may flow from the capacitors within the plasma and chamber 630 through the inductor L12 to charge the power supply C15 until the voltage across the inductor L12 is zero. The diode D9 may prevent the capacitors within the plasma and chamber 630 from ringing with the inductance in the plasma and chamber 630 or the bias compensation circuit 625.

The diode D12 may, for example, prevent charge from flowing from the power supply C15 to the capacitors within the plasma and chamber 630.

The value of inductor L12 can be selected to control the current fall time. In some embodiments, the inductor L12 can have an inductance value between 1 pH-500 μH.

In some embodiments, the energy recovery circuit 905 may include a switch that can be used to control the flow of current through the inductor L12. The switch, for example, may be placed in series with the inductor L12. In some embodiments, the switch may be closed when the switch S1 is open and/or no longer pulsing to allow current to flow from the plasma and chamber 630 back to the power supply C15.

A switch in the energy recovery circuit 905, for example, may include a high voltage switch such as, for example, the high voltage switch disclosed in U.S. patent application Ser. No. 16/178,565 filed Nov. 1, 2018, titled “HIGH VOLTAGE SWITCH WITH ISOLATED POWER,” which claims priority to U.S. Provisional Patent Application No. 62/717,637 filed Aug. 10, 2018, both of which are incorporated by reference in the entirety. In some embodiments, the RF driver 605 may include a high voltage switch in place of or in addition to the various components shown in RF driver 605. In some embodiments, using a high voltage switch may allow for removal of at least the transformer T1 and the switch S1.

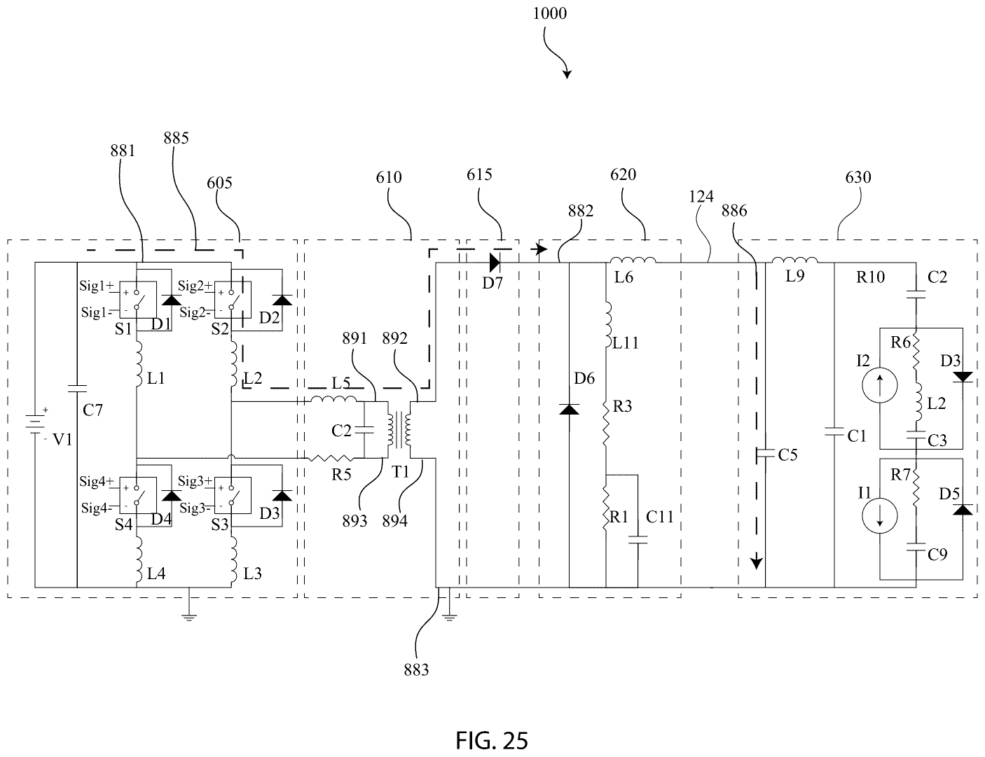

FIG. 25 is a circuit diagram of a driver and chamber circuit 1000 according to some embodiments. The driver and chamber circuit 1000, for example, may include the RF driver 605, the resonant circuit 610, the resistive output stage 620, and the plasma and chamber 630. Thus, driver and chamber circuit 1000 is similar to the driver and chamber circuit 600 without the bias compensation circuit 625.

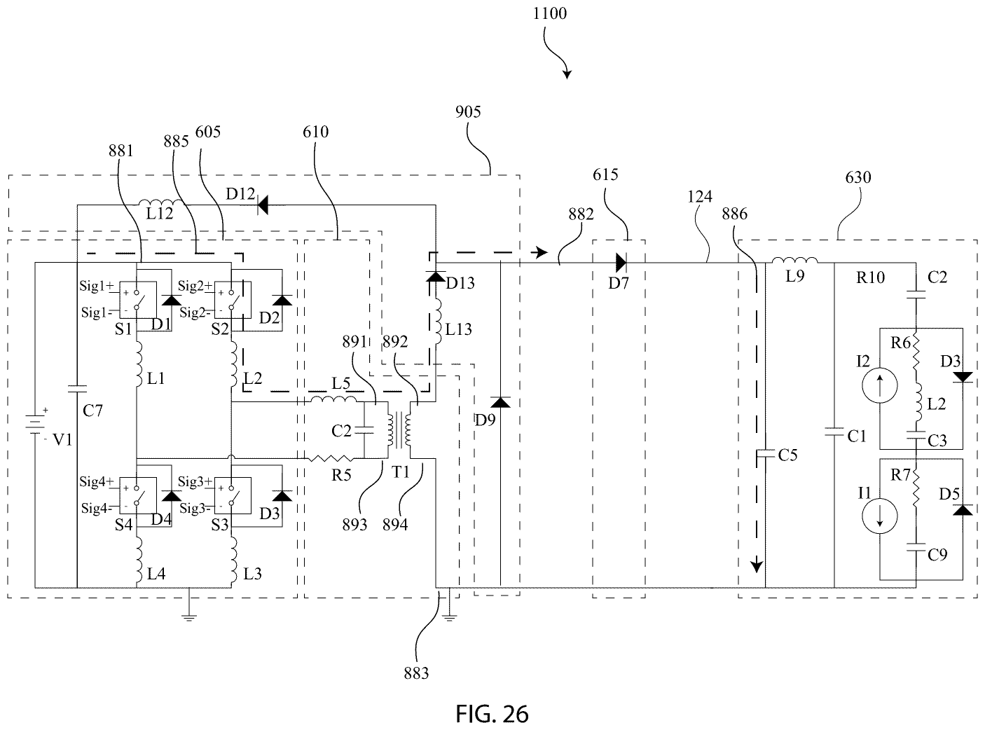

FIG. 26 is a circuit diagram of a driver and chamber circuit 1100 according to some embodiments. The driver and chamber circuit 1100, for example, may include the RF driver 605, the resonant circuit 610, the energy recovery circuit 905, and the plasma and chamber 630. Thus, driver and chamber circuit 1100 is similar to the driver and chamber circuit 900 without the bias compensation circuit 625.

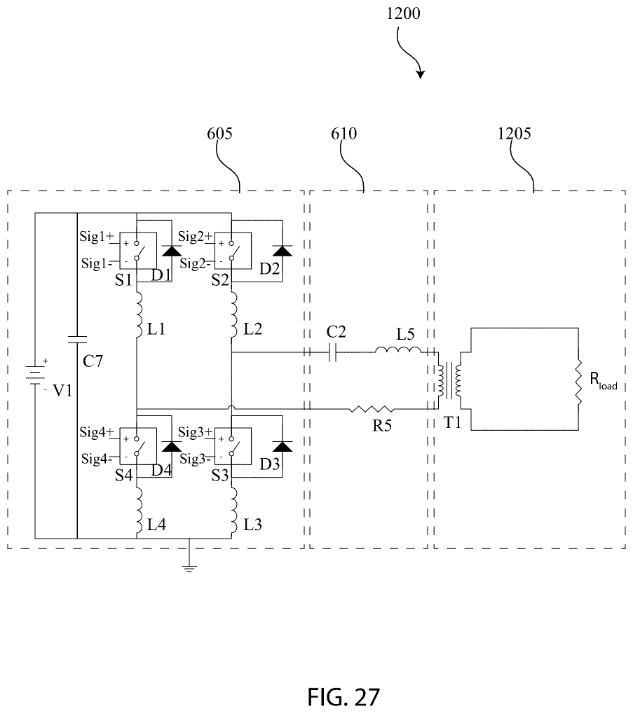

FIG. 27 is a circuit diagram of a driver and an inductive discharge plasma 1200 according to some embodiments. The driver and an inductive discharge plasma 1200, for example, may include the RF driver 605, the resonant circuit 610, and an inductively discharged plasma 1205. In this example, the inductor L5 may include the antenna that is coupled with the inductively discharged plasma 1205. The transformer T1 may represent how the inductively discharged plasma 1205 couples with the antenna, which is represented at least in part by the inductor L5. The capacitor C2 may resonate with the inductor L5 to determine the resonate frequency. The RF driver 605 may produce pulses that are driven with this resonant frequency.

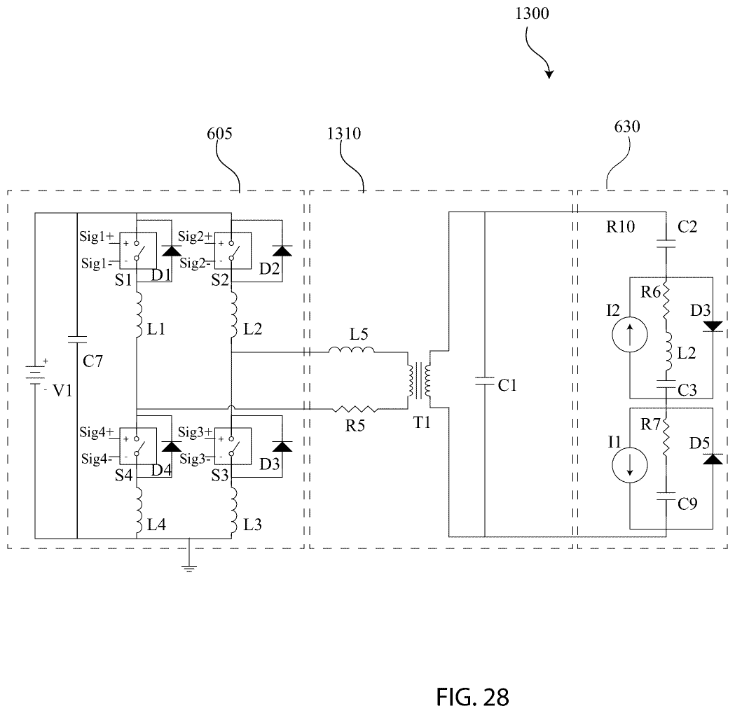

FIG. 28 is a circuit diagram of a driver and a capacitive discharge plasma 1300 according to some embodiments. The driver and a capacitive discharge plasma 1300, for example, may include the RF driver 605, the resonant circuit 1310, which may include the transformer, and the chamber 630. The capacitor C1 may represent the capacitance of the discharge geometry, any stray capacitance in the circuit, or the capacitance of any capacitors in the circuit. L5 may represent the inductance of any stray inductance in the circuit or the inductance of any inductance in the circuit. The RF driver 605 may drive the resonant circuit 1310 with a pulse frequency that is substantially equal to the resonate frequency of the resonant circuit.

In some embodiments, each switch S1, S2, S3, or S4 in the resonant circuit 605 can be switched independently or in conjunction with one or more of the other switches. For example, the signal Sig1 may be the same signal as signal Sig3. As another example, the signal Sig2 may be the same signal as signal Sig4. As another example, each signal may be independent and may control each switch S1, S2, S3, or S4 independently or separately.

In some embodiments, the transformer T1 may or may not be included in the driver and a capacitive discharge plasma 1300.

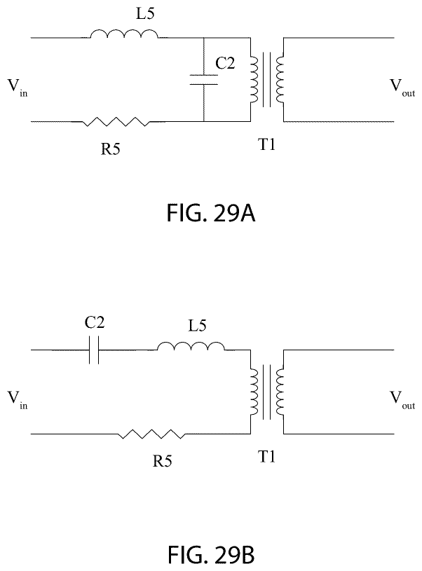

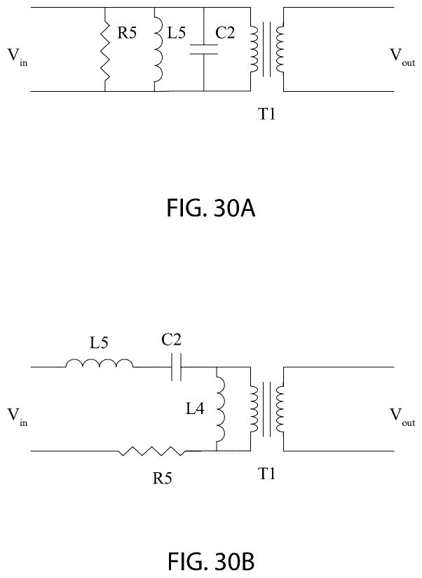

FIGS. 29A, 29B, 30A, and 30B are circuit diagrams of example resonant circuits that may be used in place of resonant circuit 610 in FIG. 21. These circuits may or may not include the transformer shown in each figure.

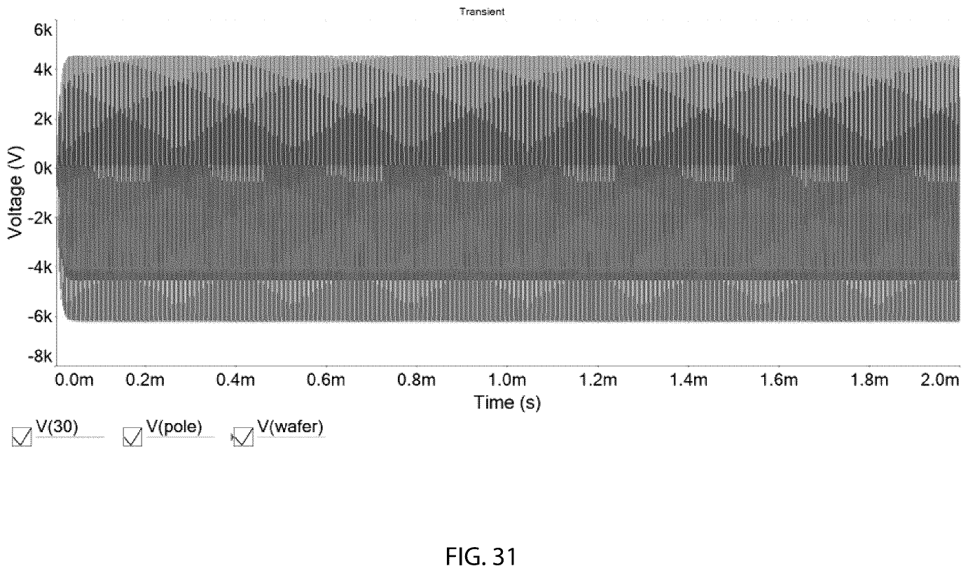

FIG. 31 is a continuous waveform of the voltage across the transformer T1 (red), at the Pole (green), and at the wafer (blue).

FIG. 32 is a short burst waveform of the voltage across the transformer T1 (red), at the Pole (green), and at the wafer (blue). This waveform shows a 22.5 μs long burst.

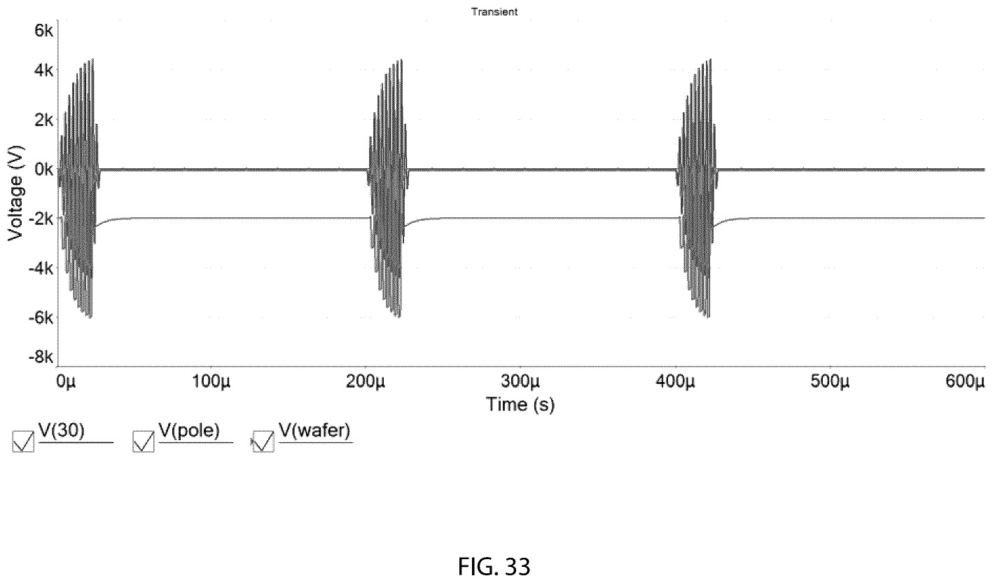

FIG. 33 is a waveform showing a series of short bursts across the transformer T1 (red), at the Pole (green), and at the wafer (blue). This waveform shows repeated 22.5 μs long bursts. Embodiments described within this document provide a system whose timing can be adjusted. For example, the number of pulses in a burst, the frequency, the number of bursts, and/or the duty cycle of bursts can all be adjusted by changing the drive signal(s) (Sig1, Sig2, Sig3, or Sig4) to the switches S1, S2, S3, or S4.

In some embodiments, the diode D8 and the capacitor C7 in the bias compensation circuit 625 shown in any circuit can be arranged in a stripline such that the current flows in a U-shaped path. A stripline, for example, may be a transmission line trace surrounded by dielectric material suspended between two ground planes on internal layers of a PCB. In some embodiments, the separation between the diode D8 and the capacitor C7 can be maximized. In some embodiments, the diode D8 and the capacitor C7 stripline as wide as possible such as, for example, 10, 8, 6, 4, 3, 2, 1, ½ inches.

In some embodiments, the lead inductance L22 can be minimized or eliminated by connecting the point 124 to the input of the diode D8 (e.g., at the stray inductance L22). In some embodiments, the lead inductance L24 can be minimized or eliminated by connecting the low side of the capacitor C7 (e.g., at the stray inductance L24) directly to ground.

In this example, the bias compensation circuit 625 includes stray inductance L22 between diode D8 and the position labeled 124, stray inductance L23 between diode D8 and capacitor C7, or stray inductance L24 between capacitor C7 and ground. The circuit 500 includes plasma side inductance Lₚ and switch side inductance Lₛ. The plasma side stray inductance Lₚ, for example, may include all the inductance whether stray, parasitic, or from any element between the bias compensation circuit 625 and the chamber 630 such as, for example, L9 and any other stray inductance on this side of the circuit. The switch side inductance Lₛ, for example, may include all the inductance whether stray, parasitic, or from any element between the bias compensation circuit 625 and the switch S1 such as, for example, L11, L5, L1, L2, L3, and/or LA, and any other stray inductance on this side of the circuit.

In some embodiments, the switch side inductance Lₛ should be greater than the plasma side stray inductance Lₚ. In some embodiments, the plasma side stray inductance Lₚ is 20% of the switch side inductance Lₛ. In some embodiments, the plasma side stray inductance Lₚ is less than about 1 nH, 10 nH, 100 nH, 1 μH, etc.

In some embodiments, the stray inductance L22 has an inductance less than about 1 nH, 10 nH, 100 nH, 1 μH, etc. In some embodiments, the stray inductance L23 has an inductance less than about 1 nH, 10 nH, 100 nH, 1 μH, etc. In some embodiments, the stray inductance L24 has an inductance less than about 1 nH, 10 nH, 100 nH, 1 μH, etc. In some embodiments the sum of the stray inductance of L22, L23, and L24 is less than about 1 nH, 10 nH, 100 nH, 1 μH, etc.

In some embodiments, the stray inductance L22, L23, or L24 can be minimized In a variety of ways. For example, the conductor along stray inductance L22, L23, or L24 can be broader than industry standard such as, for example, greater than ⅛, ¼, ⅜, ½, 1, 2.5, 5 inches etc. As another example, various circuit elements, such as, for example, diode D8 or capacitor C7 may include a plurality of diodes or capacitors in parallel or series.

In some embodiments, the distance between elements may be minimized to reduce stray inductance. For example, the top conductor and the bottom conductor between which the various bias compensation circuit elements may be separated by less than about 1, 2, 5, 15, 20, 25, 30, 35, 40 cm. As another example, the discrete elements comprising diode D8 may be disposed within less than 10, 8, 6, 4, 3, 2, 1, ½ inches from the position labeled 124 or ground. As another example, the discrete elements comprising capacitor C7 may be disposed within less than 10, 8, 6, 4, 3, 2, 1, ½ inches from the position labeled 124 or ground.

In some embodiments, the volume of the discrete elements comprising either or both the diode D8 and/or capacitor C7 may be less than 1200, 1000, 750, 500 cubic centimeters.

In some embodiments, a resistor R4 may be included across diode D8. In some embodiments, the resistor R4 may have resistance values of less than about 1 kΩ to 1 MΩ such as, for example, less than about 100 kΩ.

In some embodiments, the capacitor C7 may have a capacitance less than about 1 pF or less than about 1 mF. The capacitor C7 may have a stray inductance less than about 1 nH, 10 nH, 100 nH, 1 μH, etc.

Unless otherwise specified, the term “substantially” means within 5% or 10% of the value referred to or within manufacturing tolerances. Unless otherwise specified, the term “about” means within 5% or 10% of the value referred to or within manufacturing tolerances.

The term “or” is inclusive.

Numerous specific details are set forth herein to provide a thorough understanding of the claimed subject matter. However, those skilled in the art will understand that the claimed subject matter may be practiced without these specific details. In other instances, methods, apparatuses or systems that would be known by one of ordinary skill have not been described in detail so as not to obscure claimed subject matter.

Some portions are presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm is a self-consistent sequence of operations or similar processing leading to a desired result. In this context, operations or processing involves physical manipulation of physical quantities. Typically, although not necessarily, such quantities may take the form of electrical or magnetic signals capable of being stored, transferred, combined, compared or otherwise manipulated. It has proven convenient at times, principally for reasons of common usage, to refer to such signals as bits, data, values, elements, symbols, characters, terms, numbers, numerals or the like. It should be understood, however, that all of these and similar terms are to be associated with appropriate physical quantities and are merely convenient labels. Unless specifically stated otherwise, it is appreciated that throughout this specification discussions utilizing terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

The system or systems discussed herein are not limited to any particular hardware architecture or configuration. A computing device can include any suitable arrangement of components that provides a result conditioned on one or more inputs. Suitable computing devices include multipurpose microprocessor-based computer systems accessing stored software that programs or configures the computing system from a general-purpose computing apparatus to a specialized computing apparatus implementing one or more embodiments of the present subject matter. Any suitable programming, scripting, or other type of language or combinations of languages may be used to implement the teachings contained herein in software to be used in programming or configuring a computing device.

Embodiments of the methods disclosed herein may be performed in the operation of such computing devices. The order of the blocks presented in the examples above can be varied—for example, blocks can be re-ordered, combined, and/or broken into sub-blocks. Certain blocks or processes can be performed in parallel.

The use of “adapted to” or “configured to” herein is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Headings, lists, and numbering included herein are for ease of explanation only and are not meant to be limiting.

While the present subject matter has been described in detail with respect to specific embodiments thereof, it will be appreciated that those skilled in the art, upon attaining an understanding of the foregoing, may readily produce alterations to, variations of, and equivalents to such embodiments. Accordingly, it should be understood that the present disclosure has been presented for purposes of example rather than limitation, and does not preclude inclusion of such modifications, variations and/or additions to the present subject matter as would be readily apparent to one of ordinary skill in the art.

That which is claimed:

1. An apparatus to apply a periodic voltage comprising:
a switch coupled to a first node and a second node;
a first voltage source coupled to the first node and a third node;
a second voltage source coupled to the second node and third node; and
a controller configured to:
close the switch to connect and disconnect a current pathway between the first node and the second node to cause an application of an asymmetric periodic voltage waveform at the second node relative to the third node,
wherein each cycle of the asymmetric periodic voltage waveform includes a first portion that begins with a first negative voltage and changes to a positive peak voltage, a second portion that changes from the positive peak voltage to a third voltage level and a fourth portion that includes a negative voltage ramp from the third voltage level to a fourth voltage level.

2. The apparatus of claim 1, wherein connecting the current pathway between the first node and the second node causes the first portion of the asymmetric periodic voltage waveform that begins with a first negative voltage and changes to the positive peak voltage.

3. The apparatus of claim 2, wherein disconnecting the current pathway causes the second portion of the asymmetric periodic voltage waveform that changes from the positive peak voltage level to the third voltage level.

4. The apparatus of claim 1, wherein the second voltage source is in series with an inductive element and the second voltage source and the inductive element are coupled between the second node and the third node.

5. The apparatus of claim 4, wherein the switch is arranged in series with a first diode and a first inductor, and the switch, first diode, and the first inductor are coupled between the first node and the second node.

6. The apparatus of claim 5, a second inductor is arranged in series with a second diode, and the second inductor and the second diode are coupled between the second node and the third node.

7. The apparatus of claim 6, the second voltage source is arranged in series with a third inductor, Lb, and the second voltage source and the third inductor are arranged between the second node and the third node.

8. The apparatus of claim 1, wherein the switch includes a plurality of switches arranged is series.

9. The apparatus of claim 1, wherein the switch includes a plurality of switches arranged in parallel.

10. A method comprising:
applying a first voltage between a first node and a third node;
applying a second voltage between the second node and a third node
connecting and disconnecting a current pathway between the first node and the second node to cause an application of an asymmetric periodic voltage waveform at the second node, wherein each cycle of the asymmetric periodic voltage waveform includes a first portion that begins with a first negative voltage and changes to a positive peak voltage, a second portion that changes from the positive peak voltage to a third voltage level and a fourth portion that includes a negative voltage ramp from the third voltage level to a fourth voltage level.

11. The apparatus of claim 10, wherein the connecting and disconnecting causes unidirectional current through the current pathway between the first node and the second node.

12. The method of claim 11, wherein the connecting and disconnecting causes unidirectional current through a second current pathway between the second node and the third node.

13. A bias supply to apply a periodic voltage comprising:
an output node;
a return node;
a power section coupled to the output node and the return node;
a resonant switch section coupled to the power section at a first node, a second node, and a third node wherein the resonant switch section is configured to connect and disconnect a current pathway between the first node and the second node to cause an application of an asymmetric periodic voltage waveform at the output node relative to the return node, wherein each cycle of the asymmetric periodic voltage waveform includes a first portion that begins with a first negative voltage and changes to a positive peak voltage, a second portion that changes from the positive peak voltage level to a third voltage level and a fourth portion that includes a negative voltage ramp from the third voltage level to a fourth voltage level; and
an offset voltage source, wherein a second node of a secondary winding of the transformer is coupled to the return node via the offset voltage source;
wherein the power section comprises:
a transformer, a first node of a primary winding of the transformer coupled to a second node of the resonant switch section, a first node of the secondary winding of the transformer coupled to the output node, and a second node of the secondary winding of the transformer coupled to the return node; and
a voltage source coupled between a second node of the primary winding of the transformer and the return node.

14. The bias supply of claim 13, wherein connecting the current pathway causes the first portion of the asymmetric periodic voltage waveform that begins with a first negative voltage and changes to the positive peak voltage.

15. The bias supply of claim 13, wherein disconnecting the current pathway causes the second portion of the asymmetric periodic voltage waveform that changes from the positive peak voltage level to the third voltage level.

16. The bias supply of claim 15, wherein the power section comprises a voltage source in series with an inductive element coupled between the second node and the return node.

17. A bias supply to apply a periodic voltage comprising:
an output node;
a return node;
a resonant switch section comprising:
a first node, a second node, and a third node;
a first current pathway between the first node and the second node, the first current pathway comprising a series combination of a switch and a diode;
a second current pathway between the second node and the third node comprising a diode and an inductive element; and
a power section comprising:
a first voltage source coupled between the third node and the first node; and
a second voltage source coupled to the return node;
wherein closing the switch causes unidirectional current in the first and second current pathways to cause an application of the periodic voltage between the output node and the return node.

18. The bias supply of claim 17, wherein the first current pathway is configured so the unidirectional current in the first pathway increases from zero current at a time t0 when the switch is closed to a peak value and then decreases back to zero at a time t1 when the switch is opened and a voltage between the output node and return node increases from a negative voltage at the time t0 to a peak value at the time t1.

19. The bias supply of claim 17, wherein the first current pathway comprises a series combination of the switch, inductive element, and the diode coupled between the first node and the second node.

20. The bias supply of claim 17, wherein the first current pathway comprises two inductive elements that are coupled together at the second node.

21. The bias supply of claim 17, wherein the power section comprises a series combination of the second voltage source and an inductive element coupled between the output node and the return node.

22. The bias supply of claim 17, wherein the second voltage source is coupled between the second node and the return node.

23. The bias supply of claim 17, wherein a negative terminal of the second voltage source is coupled to a negative terminal of the first voltage source.

24. The bias supply of claim 17, comprising a third voltage source coupled between the third node and the return node.

25. An apparatus to apply a periodic voltage comprising:
an output node;
a return node;
a switch and a first diode arranged in series within a first current pathway between a first node and a second node;
a second current pathway between the second node and a third node comprising a second diode; and
a first voltage source coupled between the first node and the third node; and
a second voltage source coupled to the return node;
wherein closing the switch causes unidirectional current in the first and second current pathways to cause an application of the periodic voltage between the output node and the return node.

26. The apparatus of claim 25, wherein the connecting and disconnecting causes unidirectional current through the current pathway between the first node and the second node.

27. The apparatus of claim 26, wherein the connecting and disconnecting causes unidirectional current through a second current pathway between the second node and the third node.

28. The apparatus of claim 25, wherein the first current pathway comprises two inductive elements that are coupled together at the second node.

29. The apparatus of claim 25, wherein a series combination of the second voltage source and an inductive element coupled between the output node and the return node.

30. The apparatus of claim 25, wherein the second voltage source is coupled between the second node and the return node.

31. The apparatus of claim 25, wherein a negative terminal of the second voltage source is coupled to a negative terminal of the first voltage source.
